(19) United States
(12) Patent Application Publication
(10) Pub. No.: US 2024/0276752 A1
(43) Pub. Date: Aug. 15, 2024

(54) ORGANIC LIGHT EMITTING ELEMENT

(71) Applicant: CANON KABUSHIKI KAISHA, Tokyo (JP)

(72) Inventors: Itaru TAKAYA, Kanagawa (JP); Naoki YAMADA, Tokyo (JP); Hirokazu MIYASHITA, Miyagi (JP)

(21) Appl. No.: 18/423,119

(22) Filed: Jan. 25, 2024

(30) Foreign Application Priority Data
Jan. 31, 2023 (JP) 2023-012669

(51) Int. Cl. H10K 50/12; H10K 101/40

(52) U.S. Cl. CPC H10K 50/121; H10K 2101/40

(57) ABSTRACT

In an organic light emitting element that includes an adjacent layer in contact with a cathode side of a light emission layer containing a host material and a light emitting dopant material, the adjacent layer is composed of an adjacent layer material having a bandgap of 3.0 eV or less, and the materials are selected so that the difference between an energy value at a peak wavelength of an emission spectrum of the adjacent layer material and an energy value at a longest wavelength-side peak wavelength in an absorption spectrum of the host material is 0.15 eV or less.

### BACKGROUND

### Technical Field

The aspect of the embodiments relates to an organic light emitting element, and various appliances and apparatuses that include the organic light emitting element.

### Description of the Related Art

An organic light emitting element (also referred to as an “organic electroluminescence element” or an “organic EL element”) has a layered structure having an anode/light emission layer/cathode basic structure, and emits light as holes from the anode and electrons from the cathode recombine in the light emission layer. For the purposes of improving light emission efficiency and durability characteristics, a multilayer structure such as an anode/hole injection layer/hole transport layer/electron blocking layer/light emission layer/hole blocking layer/electron transport layer/electron injection layer/cathode is sometimes employed. Here, the hole blocking layer is disposed in contact with the cathode side of the light emission layer in order to prevent leakage of holes from the light emission layer toward the cathode and to prevent degradation of light emission efficiency.

In order for a layer (hereinafter referred to as an “adjacent layer”) in contact with the cathode side of the light emission layer to function as a hole blocking layer, the HOMO level of the adjacent layer needs to be smaller than the HOMO level of the host material in the light emission layer. If the HOMO level of the adjacent layer is larger than the HOMO level of the host material, the hole blocking property is lost, holes leak into the adjacent layer, recombination occurs not in the light emission layer but in the adjacent layer, and the light emission efficiency decreases. The lower the HOMO level of the adjacent layer compared to the HOMO level of the host material, the higher the hole blocking performance of the adjacent layer.

Japanese Patent Laid-Open No. 2016-58497 discloses an organic light emitting element that includes a hole blocking layer containing a material that includes a chrysene moiety in its molecular structure.

As mentioned above, in order to have the adjacent layer function as a hole blocking layer and to obtain an element having high light emission efficiency, a material with a low HOMO level needs to be selected; however, in general, materials that include a chrysene moiety in their molecular structure and have a low HOMO level mostly have a wide bandgap and the LUMO level thereof tends to be high. If a material with a high LUMO level is used in the adjacent layer, electrons from the cathode are obstructed from entering the adjacent layer, and the voltage of the element increases. In other words, in selecting the adjacent layer, achieving both high light emission efficiency and low element voltage has become an issue.

### SUMMARY

An aspect of the embodiment provides an organic light emitting element that includes an anode, a cathode, a light emission layer disposed between the anode and the cathode, and an adjacent layer disposed in contact with a side of the light emission layer, the side facing the cathode.

The light emission layer contains a host material and a light emitting dopant material. The adjacent layer contains an adjacent layer material having a bandgap of 3.0 eV or less. A difference between an energy value at a peak wavelength of an emission spectrum of the adjacent layer material and an energy value at a peak wavelength of a longest-wavelength absorption band in an absorption spectrum of the host material is 0.15 eV or less.

Further features of the disclosure will become apparent from the following description of exemplary embodiments with reference to the attached drawings.

### BRIEF DESCRIPTION OF THE DRAWINGS

FIG. 1A is a schematic cross-sectional view of one embodiment of an organic light emitting element according to the present disclosure. FIG. 1B is an energy diagram schematically illustrating the energy levels of a light emission layer and an adjacent layer in the organic light emitting element according to the present disclosure.

FIG. 2A is a schematic diagram of a pixel of a display apparatus according to one embodiment of the present disclosure. FIG. 2B is a schematic diagram of a display apparatus according to one embodiment of the present disclosure.

FIG. 3 is a schematic diagram of a display apparatus according to one embodiment of the present disclosure.

FIG. 4A is a schematic diagram of an imaging apparatus according to one embodiment of the present disclosure. FIG. 4B is a schematic diagram of electronic equipment according to one embodiment of the present disclosure.

FIG. 5A is a schematic diagram of a display apparatus according to one embodiment of the present disclosure. FIG. 5B is a schematic diagram of a foldable display apparatus according to one embodiment of the present disclosure.

FIG. 6A is a schematic diagram of a lighting apparatus according to one embodiment of the present disclosure. FIG. 6B is a schematic diagram of an automobile that includes a vehicle lighting unit according to one embodiment of the present disclosure.

FIG. 7A is a schematic diagram illustrating one example of a wearable device according to one embodiment of the present disclosure. FIG. 7B is a schematic diagram illustrating one example of a wearable device according to one embodiment of the present disclosure equipped with an imaging apparatus.

FIG. 8A is a schematic diagram illustrating one example of an image forming apparatus according to one embodiment of the present disclosure, and FIGS. 8B and 8C are schematic diagrams illustrating examples of an exposure light source used therein.

FIG. 9A is an emission spectrum of an adjacent layer material used in Examples and Comparative Examples of the present disclosure. FIG. 9B is an emission spectrum of an adjacent layer material used in Examples of the present disclosure.

FIG. 10A is an emission spectrum of an adjacent layer material used in Examples of the present disclosure. FIG. 10B is an emission spectrum of an adjacent layer material used in Comparative Examples of the present disclosure.

FIG. 11 is an emission spectrum of an adjacent layer material used in Comparative Examples of the present disclosure.

FIG. 12A is an absorption spectrum of a host material used in Comparative Examples of the present disclosure. FIG. 12B is an absorption spectrum of a host material used in Comparative Examples of the present disclosure.

FIG. 13A is an absorption spectrum of a host material used in Examples and Comparative Examples of the present disclosure. FIG. 13B is an absorption spectrum of a host material used in Examples of the present disclosure.

FIG. 14 is an absorption spectrum of a host material used in Examples of the present disclosure.

### DESCRIPTION OF THE EMBODIMENTS

An organic light emitting element of the present disclosure includes an anode, a cathode, a light emission layer between the anode and the cathode, and an adjacent layer in contact with the cathode side (the side facing the cathode) of the light emission layer, the light emission layer containing a host material and a light emitting dopant material (hereinafter referred to as the “dopant material”). The features and embodiments of the present disclosure will now be described.

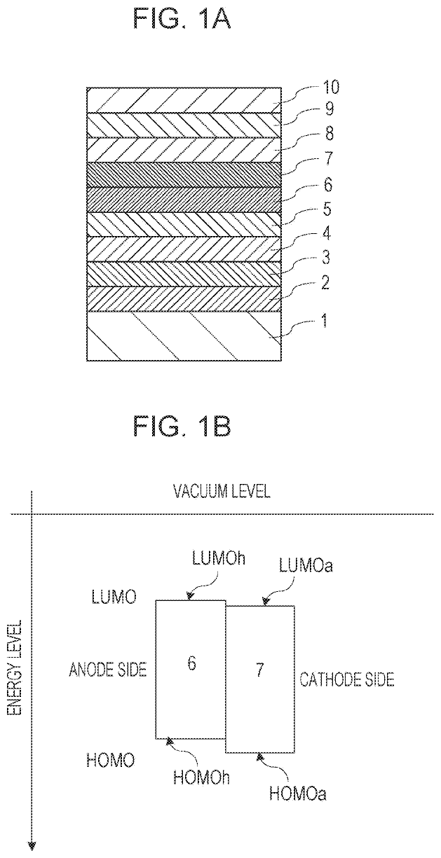

In the present disclosure, the adjacent layer contains an adjacent layer material having a bandgap of 3.0 eV or less, and the difference between the energy value at a peak wavelength of an emission spectrum of the adjacent layer material and the energy value at the longest wavelength-side peak wavelength in an absorption spectrum of the host material is 0.15 eV or less. Due to these features, the organic light emitting element of the present disclosure exhibits a low element voltage and high light emission efficiency. These features will now be described in detail with reference to FIGS. 1A and 1B.

FIG. 1A is a schematic cross-sectional view of an organic light emitting element according to one embodiment of the present disclosure. As illustrated in FIG. 1A, the organic light emitting element of the present disclosure includes at least a light emission layer 6 and an adjacent layer 7 between an anode 2 and a cathode 10, and the light emission layer 6 contains a host material and a light emitting dopant material. The adjacent layer 7 is in contact with the cathode 10-side of the light emission layer 6.

FIG. 1B is an energy diagram schematically illustrating the energy levels of the light emission layer 6 and the adjacent layer 7. In FIG. 1B, HOMOh and LUMOh respectively denote the HOMO level and the LUMO level of the host material in the light emission layer 6, and HOMOa and LUMOa respectively denote the HOMO level and the LUMO level of the adjacent layer material constituting the adjacent layer 7. The adjacent layer 7 can be solely composed of an adjacent layer material having a bandgap of 3.0 eV or less; however, as long as the effects of the present disclosure are obtained, a material having a bandgap exceeding 3.0 eV may be contained. In the description below, the case where the adjacent layer is solely composed of a material having a bandgap of 3.0 eV or less is described as an example. Consequently, in the description below, the adjacent layer material means a material having a bandgap of 3.0 eV or less. The bandgap is the difference between the HOMO level and the LUMO level, and the bandgap of the adjacent layer material is the difference between HOMOa and LUMOa illustrated in FIG. 1B. Here, the HOMO level refers to the energy level of the highest occupied molecular orbital and also recited as “HOMO”. The LUMO level refers to the energy level of the lowest unoccupied molecular orbital and also recited as “LUMO”. The HOMO level and the LUMO level are negative values, and, when the magnitudes of the HOMO and LUMO energy levels are expressed in the present disclosure, the levels that are coming closer to the vacuum level are referred to as high levels or increased levels, and the levels that are coming farther from the vacuum level are referred to as low levels or decreased levels.

A material having a bandgap of 3.0 eV or less mostly has a high HOMO level and a low LUMO level. When the HOMO level is high, the difference from the HOMO level of the host material narrows, and the hole blocking performance is weakened. However, to compensate this, the LUMO level decreases, and the element voltage can be decreased. In FIG. 1B, the LUMO level of the host material and the LUMO level of the adjacent layer material are illustrated as if the LUMO level of the adjacent layer material is lower (LUMOh>LUMOa); alternatively, in the present disclosure, the LUMO level of the host material may be lower.

Furthermore, in the present disclosure, the peak of the emission spectrum of the adjacent layer material and the peak of the longest-wavelength absorption band in the absorption spectrum of the host material overlap each other. Specifically, in one embodiment, the difference in energy value between the two peak wavelengths is 0.15 eV or less, and is more preferably 0.10 eV or less. Here, the emission spectrum of the adjacent layer material refers to a fluorescence spectrum obtained by irradiating the material with UV light. Many host materials have multiple peaks in their absorption spectra, and, in the present disclosure, of these peaks, the peak of the longest-wavelength absorption band is close to the peak of the emission spectrum of the adjacent layer material, and the two peaks overlap each other with the difference of 0.15 eV or less in energy value. The peaks of the emission spectrum and the absorption spectrum are indicated by wavelengths λ (nm). Conversion into the energy values E (eV) is given by formula (1) below, and when values are substituted into the formula, E=1240/λ.

$$E = hc / e λ \times 1 {0}^{9} \qquad ( 1 )$$

(Here, h represents a Planck's constant, c represents the speed of light, and e represents the elementary charge.)

In the present disclosure, even when the hole blocking performance of the adjacent layer material is weak and recombination occurs in the adjacent layer due to the leakage of holes from the light emission layer into the adjacent layer, energy transfer occurs from the adjacent layer to the light emission layer due to the overlap of the emission spectrum of the adjacent layer material and the absorption spectrum of the host material, and thus the efficiency is rarely degraded. The energy transfer from the adjacent layer to the light emission layer presumably occurs due to Fo\ddot{r}ster resonance energy transfer and is dependent on the overlap J given by formula (2) below between the emission spectrum of the donor and the absorption spectrum of the acceptor. The larger the wavelength of the spectrum overlap region, the larger the energy transfer.

$$J = \int fD ( λ ) ε A ( λ ) {λ}^{4} d λ \qquad ( 2 )$$

(Here, fD(λ) represents the emission spectrum of the donor relative to the peak value of 1, εA(λ) represents a molar absorptivity of the acceptor, and λ represents the wavelength.)

In the description below, optional features in the present disclosure are described in (2) to (7).

(2) When the HOMO level of the host material in the light emission layer is denoted by HOMOh and the HOMO level of the adjacent layer material is denoted by HOMOa, formula (3) below is satisfied.

$$HOMOa < HOMOh \qquad ( 3 )$$

As indicated by formula (3) above, when the HOMO level of the adjacent layer material is lower than the HOMO level of the host material of the light emission layer, the adjacent layer exhibits higher hole blocking performance for blocking holes from the light emission layer.

(3) The emission color is red.

The Förster resonance energy transfer from the adjacent layer to the light emission layer is the presumption of the present disclosure. As mentioned above, the longer the wavelength of the overlap region between the absorption spectrum of the host material in the light emission layer and the emission spectrum of the adjacent layer material, the higher the effect, and thus the organic light emitting element of the present disclosure has high light emission efficiency. The feature that the absorption spectrum of the host material has a long wavelength indicates that the bandgap of the host material is narrow, and, when the bandgap of the host material is narrow, the light emission efficiency is enhanced as the bandgap of the light emitting dopant material becomes narrower. Thus, a red light emitting dopant which has a bandgap narrower than dopants of other colors can be used in the present disclosure.

(4) The host material includes a perylene moiety in its molecular structure.

A material that includes a perylene moiety in its molecular structure has a relatively narrow bandgap among those materials that can be used as the red host materials, and can be used for the reason indicated in (3) above. Specific examples thereof are as follows. In the disclosure, the perylene moiety encompasses substituted or unsubstituted perylene groups, and structures, such as those represented by H13 to H15 below, in which a condensed polycyclic structure is further bonded to perylene.

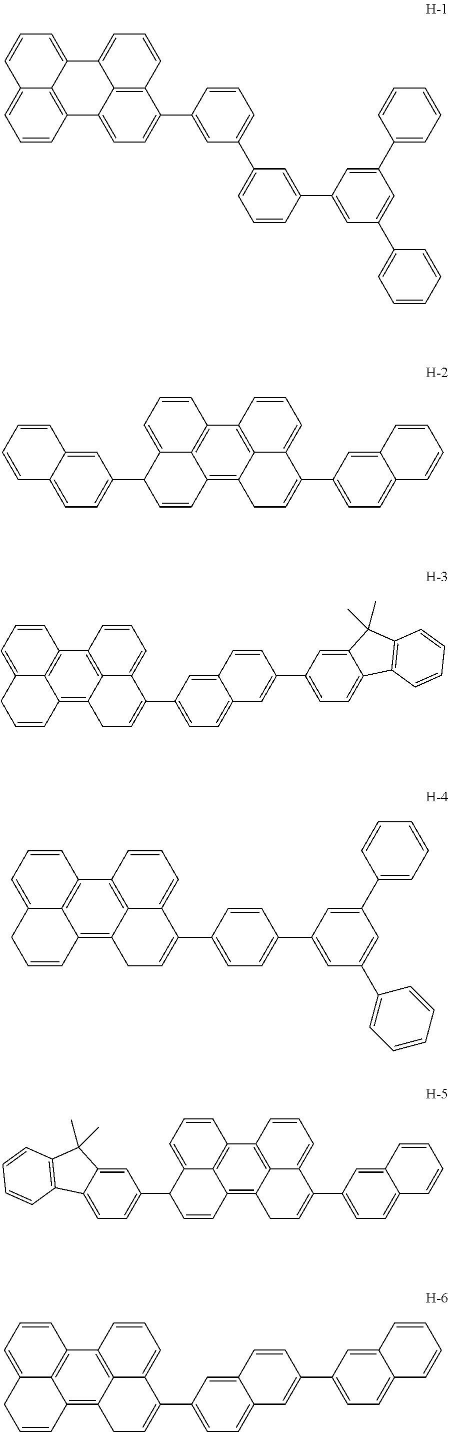

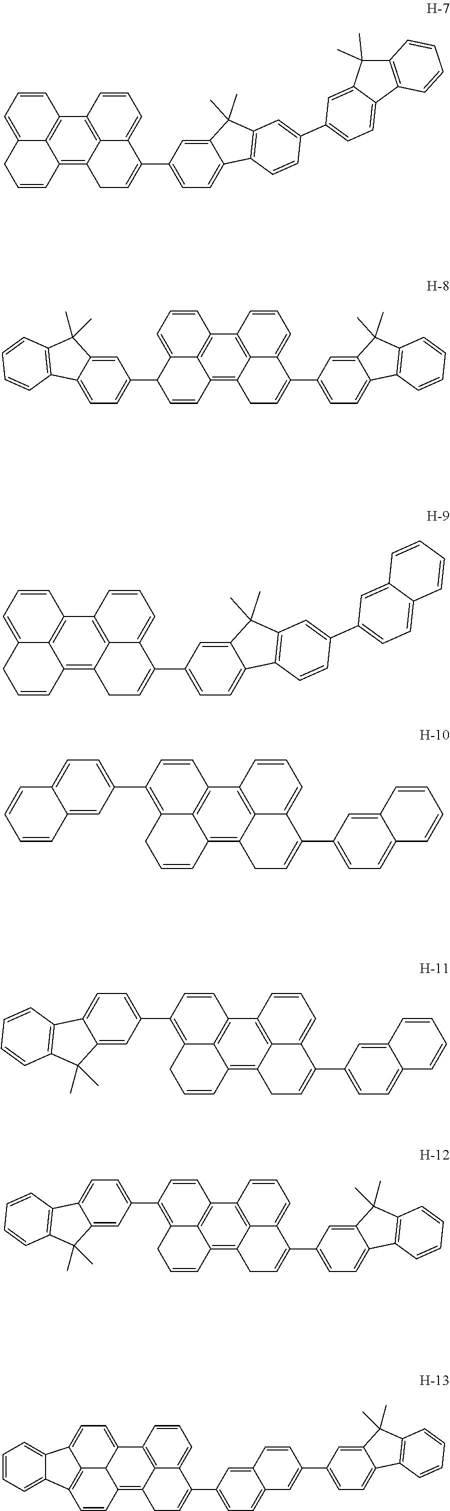

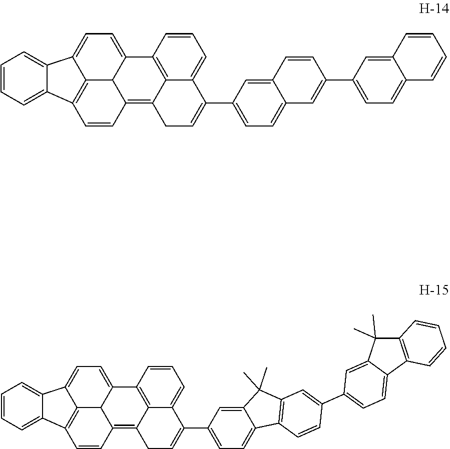

The light emission layer of the present disclosure contains a host material and a light emitting dopant material as described in (1) above. As indicated in (3) above, the emission color can be red. Specific examples of the light emitting dopant are as follows.

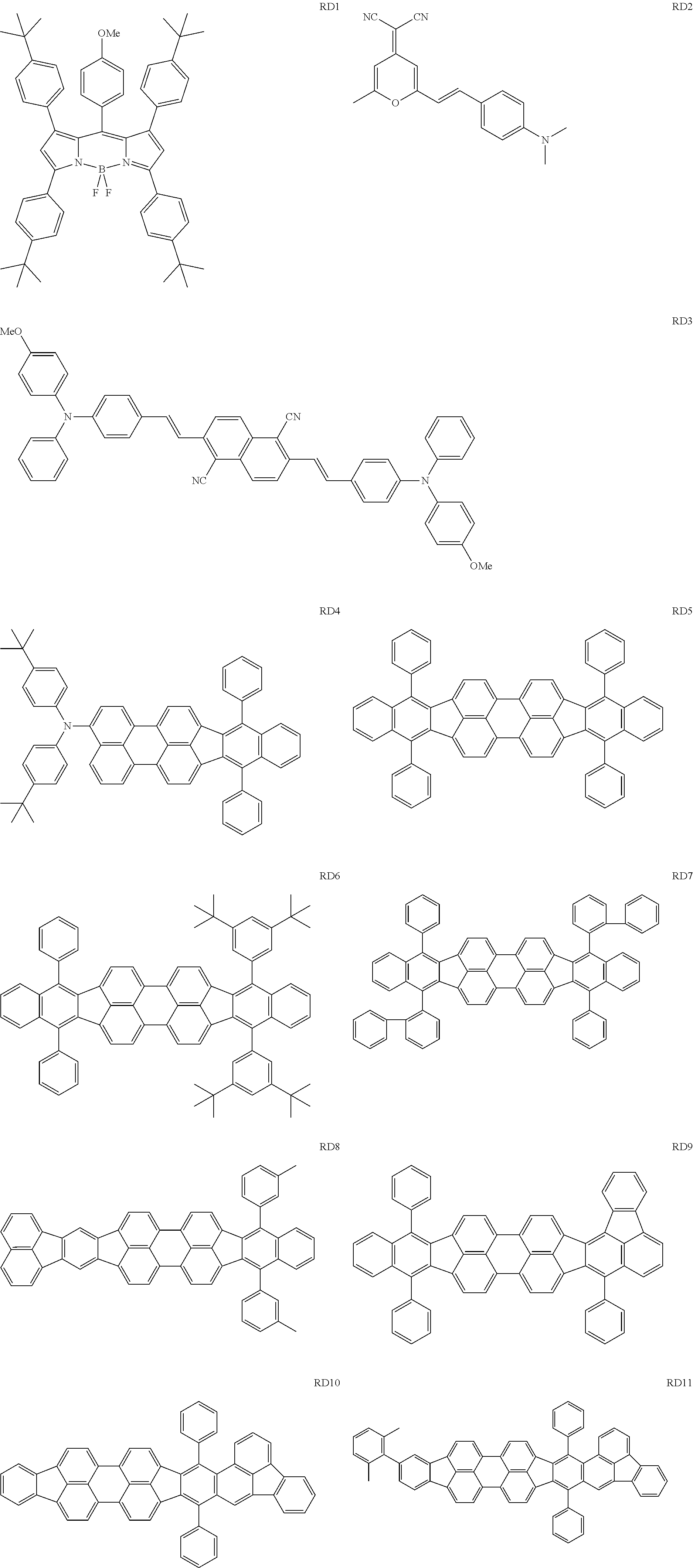

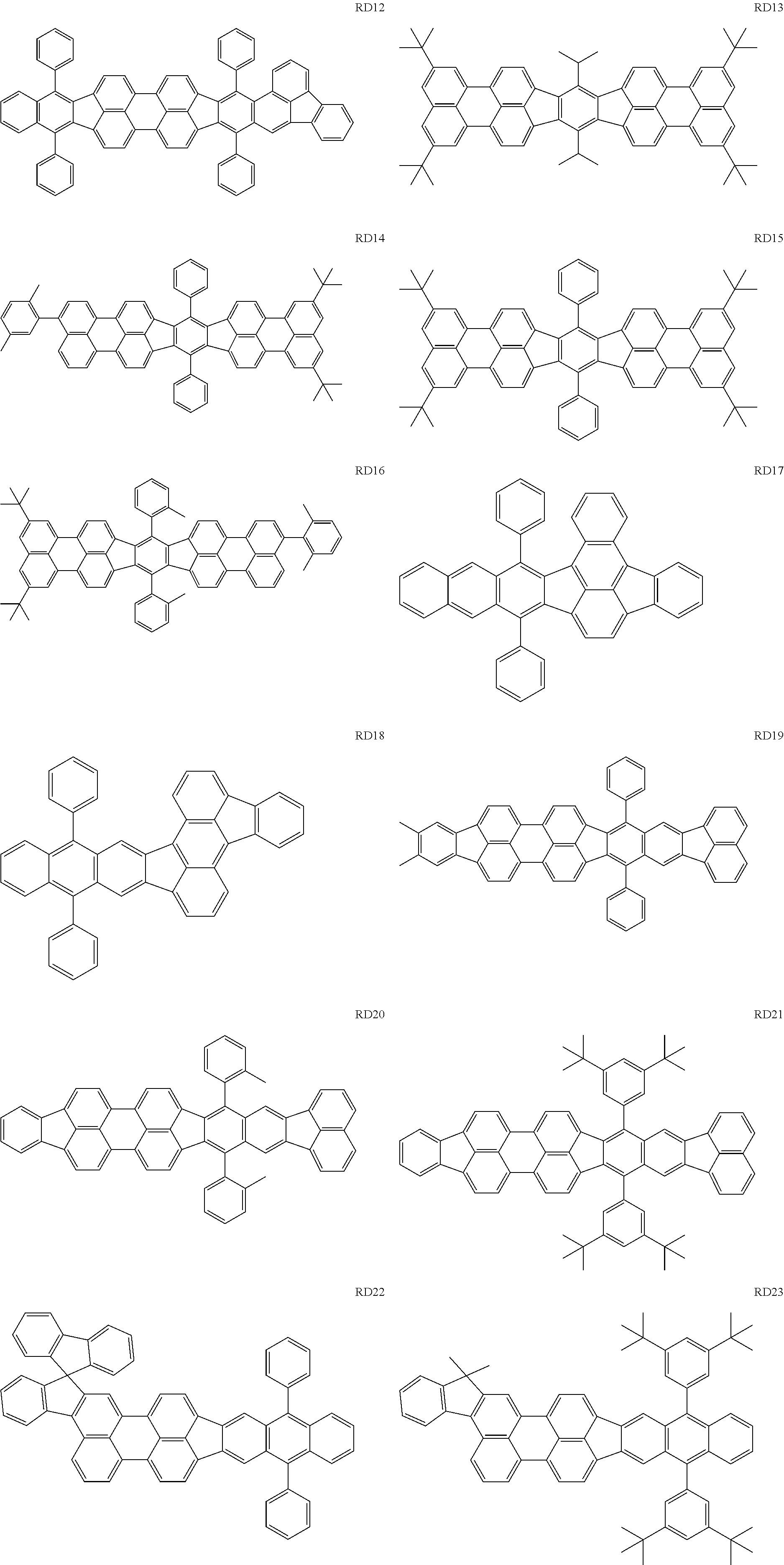

(5) The light emitting dopant material includes a perylene moiety in its molecular structure.

A light emitting dopant material that includes a perylene moiety in its molecular structure has high compatibility with a host material having a perylene moiety in its molecular structure, and disperses evenly. Thus, the dopant does not aggregate, and the light emission efficiency is increased. Thus, the structures RD4 to RD16 and RD19 to RD23 above are particularly preferable.

(6) The adjacent layer material consists of a hydrocarbon.

The adjacent layer of the present disclosure has a weak hole blocking performance and thus the presumption is that the holes would leak from the light emission layer to the adjacent layer and recombination would occur in the adjacent layer; thus, the adjacent layer can have a molecular structure that can withstand excessive radical cation generation. Thus, the adjacent layer can be solely composed of a highly chemically stable hydrocarbon that does have bonds with low bonding stability in the molecular structure. When the adjacent layer is solely composed of a hydrocarbon, driving degradation of the adjacent layer material rarely occurs during driving of the element, and the lifetime of the organic light emitting element can be extended.

Bonds with low bonding stability in the molecular structure refer to bonds, such as amino groups, that have a relatively low bonding energy and are unstable. Specifically, bonds with low bonding stability in compounds A-1, A-2, and B-1 described below are a bond between a carbazole ring and a phenylene group and a bond between an amino group and a phenyl group (nitrogen-carbon bonds). A bond between carbons, such as that in compound B-1, has higher bonding stability. Here, the bonding energy is calculated by b3-lyp/def2-SV(P).

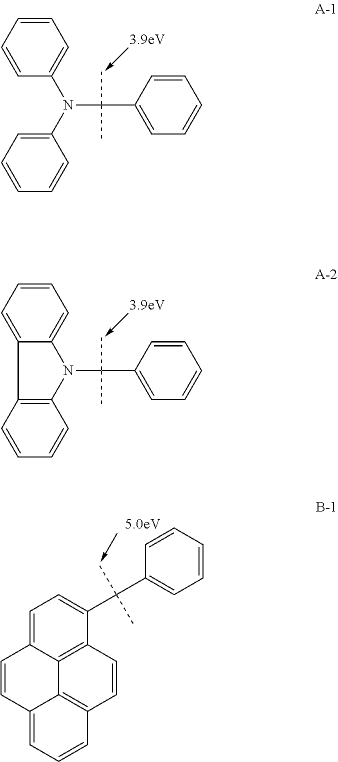

The above-described results indicate that the material constituting the adjacent layer can be solely composed of a hydrocarbon.

In particular, benzene, naphthalene, fluorene, benzofluorene, phenanthrene, chrysene, triphenylene, pyrene, fluoranthene, and benzofluoranthene have high intramolecular bonding energy since there are up to two benzene rings that are condensed linearly.

(7) The adjacent layer material includes a pyrene moiety in its molecular structure.

A material that includes a pyrene moiety in its structure has high electron mobility and can be used in the adjacent layer in contact with the cathode side of the light emission layer; furthermore, since its bandgap is relatively narrow, such a material is preferable for the reason described above. Examples of the adjacent layer material are described below, and, in the present disclosure, a the pyrene moiety encompasses substituted or unsubstituted pyrene groups, and structures, such as those represented by AD-12 to AD-14 below, in which a condensed polycyclic structure is further bonded to pyrene. Furthermore, the adjacent layer material need not contain the pyrene moiety, and AD-15 and AD-16 below are examples of the material that does not include the pyrene moiety.

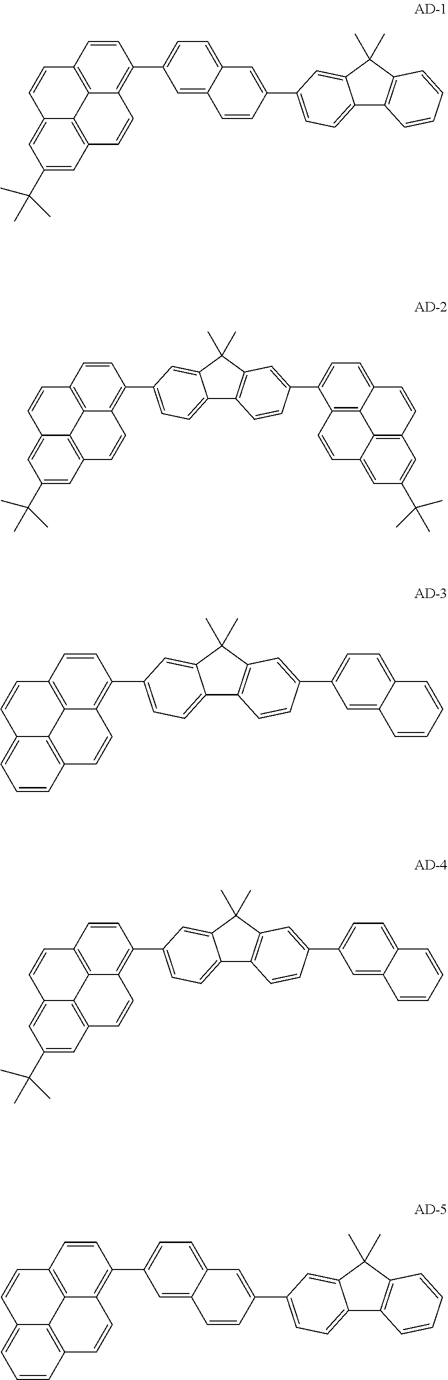

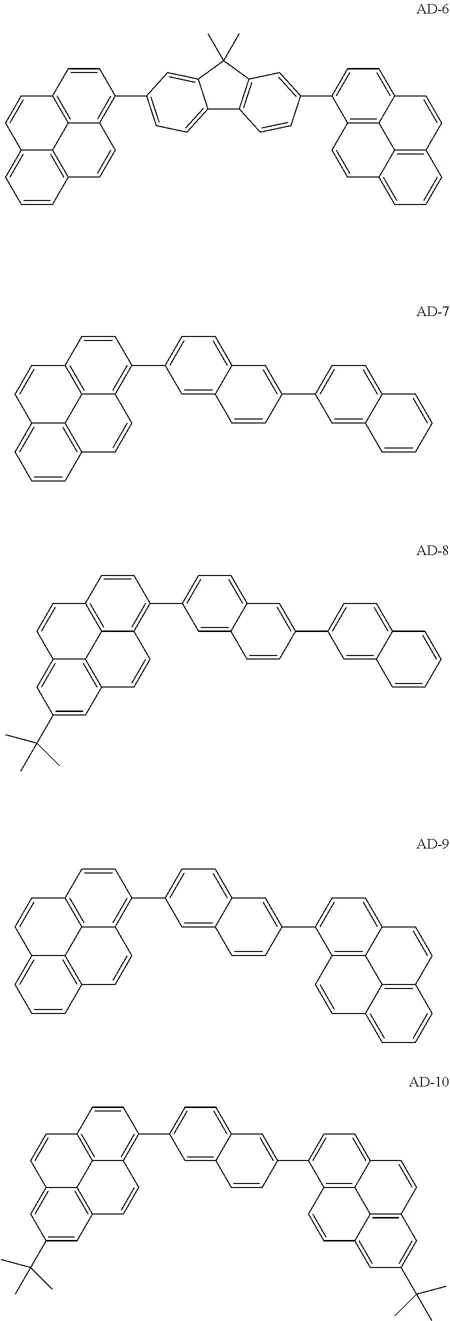

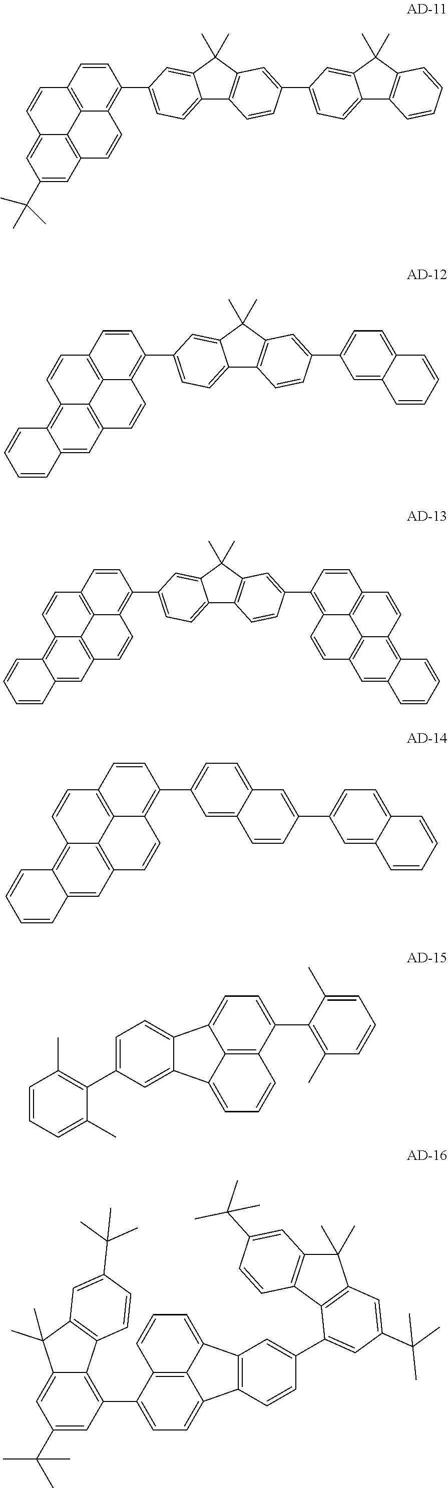

### Other Structures of the Organic Light Emitting Element

The structures of the organic light emitting element of the present disclosure other than the light emission layer and the adjacent layer will now be described.

### Electrode

The organic light emitting element of the present disclosure includes an anode and a cathode. When an electric field is applied in a direction in which the organic light emitting element emits light, the electrode with a higher potential is the anode, and the other electrode is the cathode. This can also be rephrased as that the electrode that supplies holes to the light emission layer is the anode, and the electrode that supplies electrons is the cathode.

The material constituting the anode can have a work function as large as possible. Examples of such a material that can be used include single metals such as gold, platinum, silver, copper, nickel, palladium, cobalt, selenium, vanadium, and tungsten, mixtures thereof, and alloys thereof; and metal oxides such as tin oxide, zinc oxide, indium oxide, indium tin oxide (ITO), and indium zinc oxide. In addition, conductive polymers such as polyaniline, polypyrrole, and polythiophene can be used.

These electrode substances may be used alone or two or more of these substances may be used in combination. The anode may be constituted by a single layer or multiple layers.

For use as a reflection electrode, chromium, aluminum, silver, titanium, tungsten, molybdenum, an alloy thereof, or a layered product thereof can be used. A reflection film that does not function as an electrode can also be made by using the aforementioned material. For use as a transparent electrode, an oxide transparent conductive layer such as indium tin oxide (ITO) or indium zinc oxide can be used, but this is not limiting.

Photolithography can be employed to form electrodes.

In contrast, the material constituting the cathode can have a small work function. Examples of such a material include alkali metals such as lithium, alkaline earth metals such as calcium, single metals such as aluminum, titanium, manganese, silver, lead, and chromium, and mixtures thereof. In addition, alloys of these single metals can also be used. For example, magnesium-silver, aluminum-lithium, aluminum-magnesium, silver-copper, and zinc-silver can be used. Metal oxides such as indium tin oxide (ITO) can also be used. These electrode substances may be used alone or two or more of these substances may be used in combination. The cathode may have a single layer structure or a multilayer structure. In particular, in one embodiment, silver is preferably used, and, in order to decrease aggregation of silver, silver alloys are more preferably used. The alloying ratio may be any as long as aggregation of silver can be decreased. For example, the silver-to-other metal ratio may be 1:1, 3:1, or the like.

The cathode is not particularly limited, for example, an oxide conductive layer such as ITO can be used as the cathode to form a top-emission element, or aluminum (Al) or the like can be used in the cathode to function as a reflection electrode so as to form a bottom-emission element. The method for forming the cathode may be any; however, DC or AC sputtering achieves good film coverage and easily decreases the resistance.

### Organic Compound Layers

As illustrated in FIG. 1A, the organic light emitting element according to the present disclosure may include a hole injection layer 3, a hole transport layer 4, an electron blocking layer 5, an electron transport layer 8, an electron injection layer 9, etc. Any of these layers may be provided in plurality, or any of these layers may be omitted. The layers that lie between the anode 2 and the cathode 10 are organic compound layers, but these organic compound layers may include a layer composed of or containing an inorganic compound.

Furthermore, various layer configurations may be employed, such as providing an insulating layer at the interface between an electrode and an organic compound layer, providing an adhesion layer or an interference layer, and forming the electron transport layer 8 or the hole transport layer 4 by using two layers with different ionization potentials.

The organic compound layers of the present disclosure may be formed as common layers for multiple organic light emitting elements. A common layer is a layer that straddles over multiple organic light emitting elements, and can be formed by performing a coating method such as spin coating or a vapor deposition method on the entire surface of the substrate.

Examples of the materials therefor are as follows. Examples of the material used in the hole transport layer 4 include materials that facilitate injection of holes from the anode and materials having high hole mobility capable of transporting injected holes to the light emission layer. The same material can be used in the hole injection layer 3 and the electron blocking layer 5.

In order to reduce degradation of the film quality, such as crystallization, in the organic light emitting element, a material with a high glass transition point can be used. Examples of low-molecular-weight and high-molecular-weight materials with high hole mobility include triarylamine derivatives, arylcarbazole derivatives, phenylenediamine derivatives, stilbene derivatives, phthalocyanine derivatives, porphyrin derivatives, poly(vinylcarbazole), poly(thiophene), and other conductive polymers.

Specific examples of the material used in the hole transport layer 4 are described in HT1 to HT19, but these examples are not limiting.

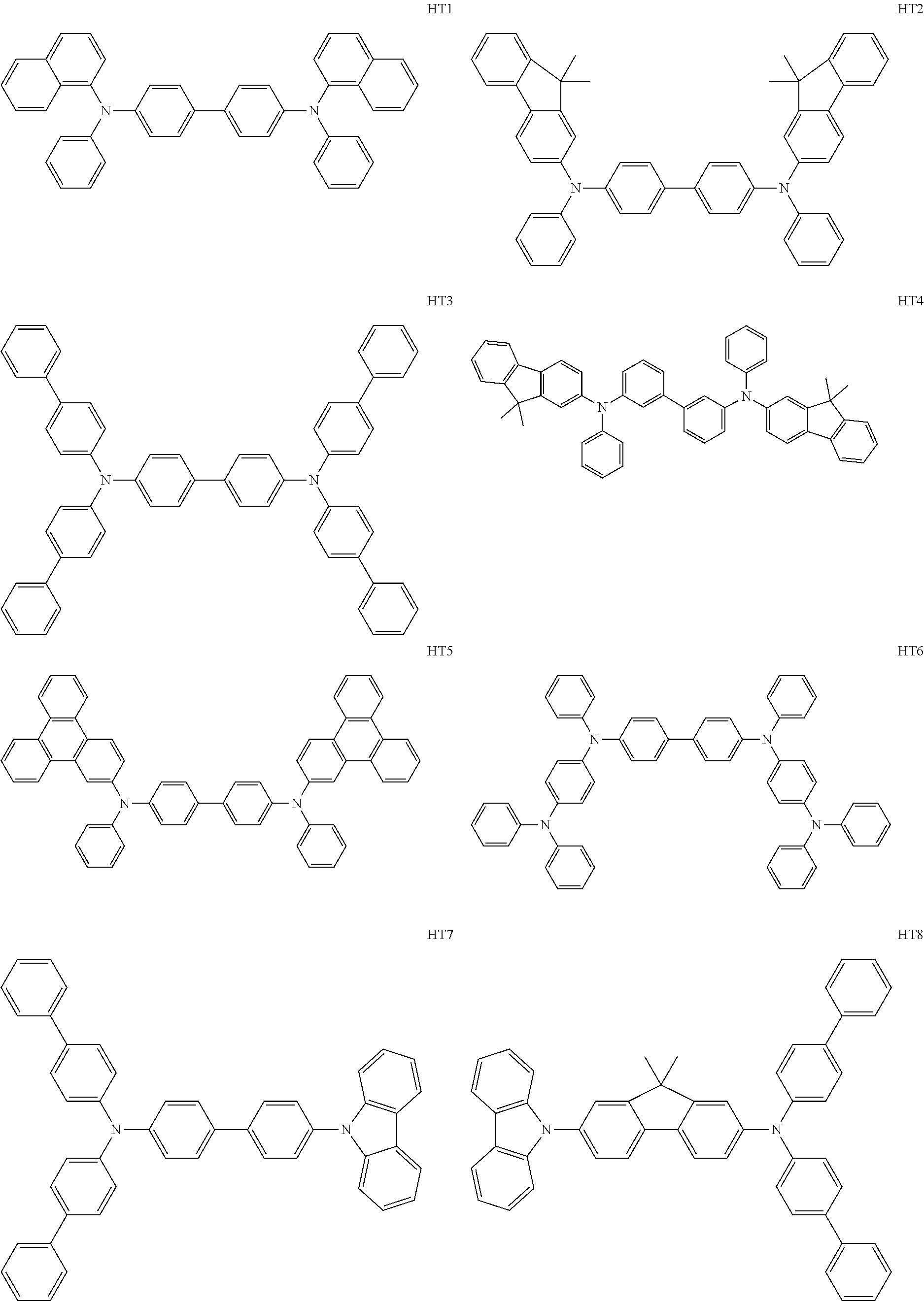

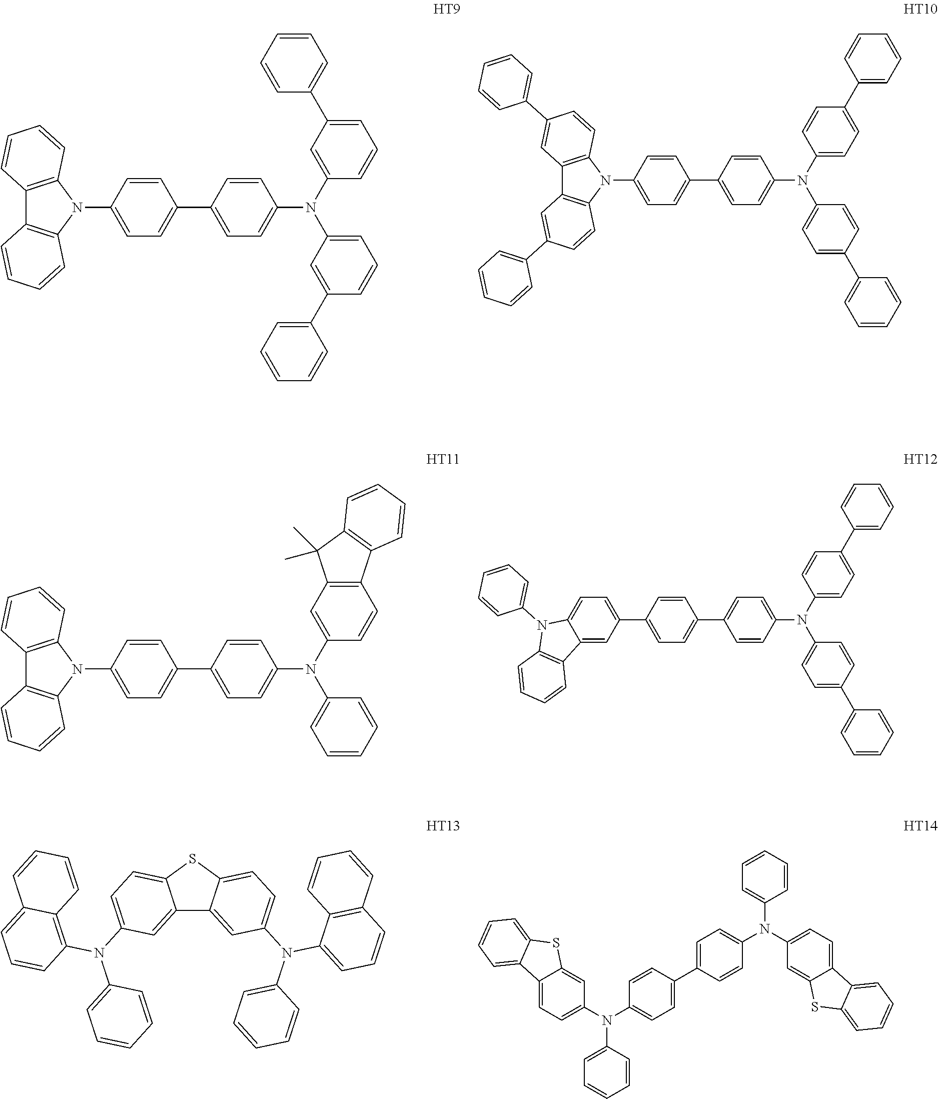

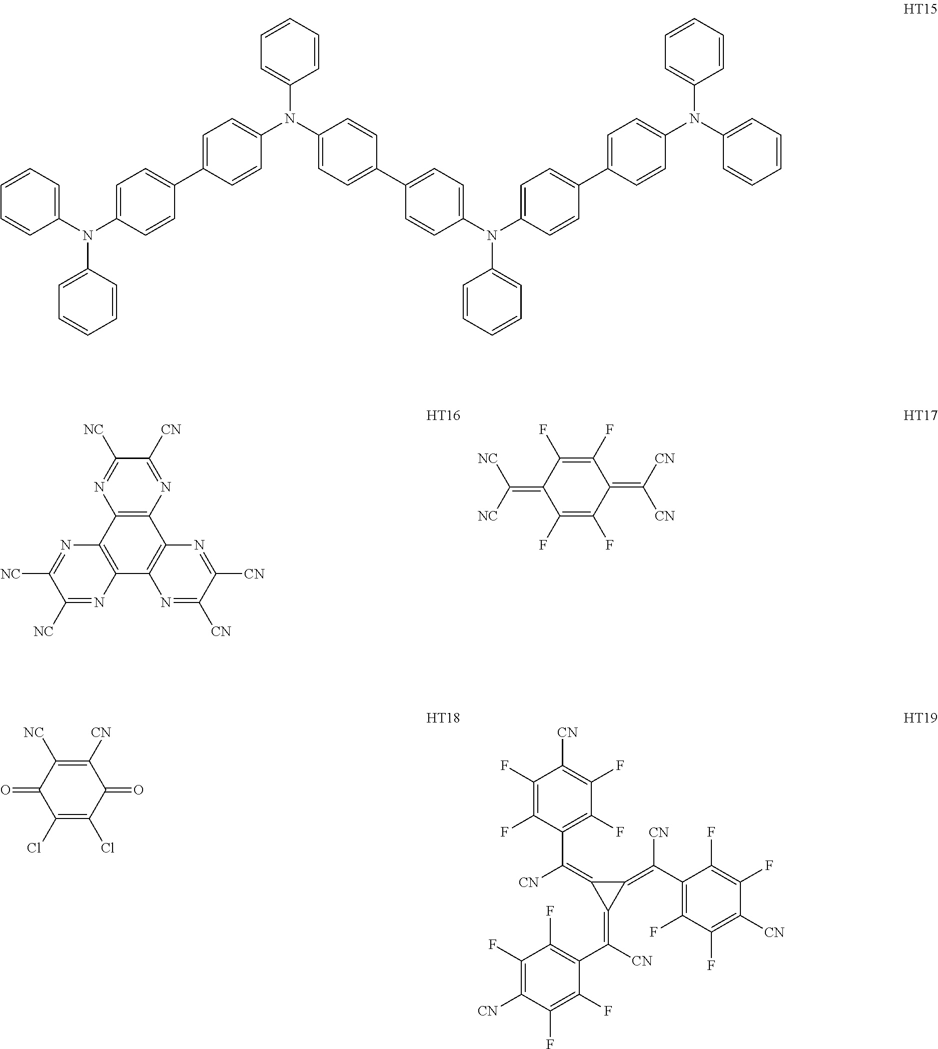

In the hole injection layer 3, a compound having a deep LUMO, such as a hexaazatriphenylene compound, a tetrafluoroquinodimethane compound, or a dichlorodicyanobenzoquinone compound, can be used. Specific examples thereof include compounds HT16 to HT19 described above.

The compounds HT7, HT8, HT9, HT10, HT11, and HT12 containing a carbazole group can be used in the electron blocking layer. By containing a carbazole group, the HOMO level becomes deeper, the level in which the HOMO levels become deeper stepwise in the order of the hole transport material, the hole blocking material, and the light emission layer can be created, and thus the holes can be injected into the light emission layer at low voltage.

The material for the electron transport layer 8 of the organic light emitting element of the present disclosure can be freely selected from those which can transfer electrons to the light emission layer 6, and is selected by considering the balance with the hole mobility of the hole transfer material, etc. Examples of the material having the electron transport capacity include, but are not limited to, oxadiazole derivatives, oxazole derivatives, pyrazine derivatives, triazole derivatives, triazine derivatives, quinoline derivatives, quinoxaline derivatives, phenanthroline derivatives, and organoaluminum complexes. Specific examples of the material used in the electron transport layer 8 are described below.

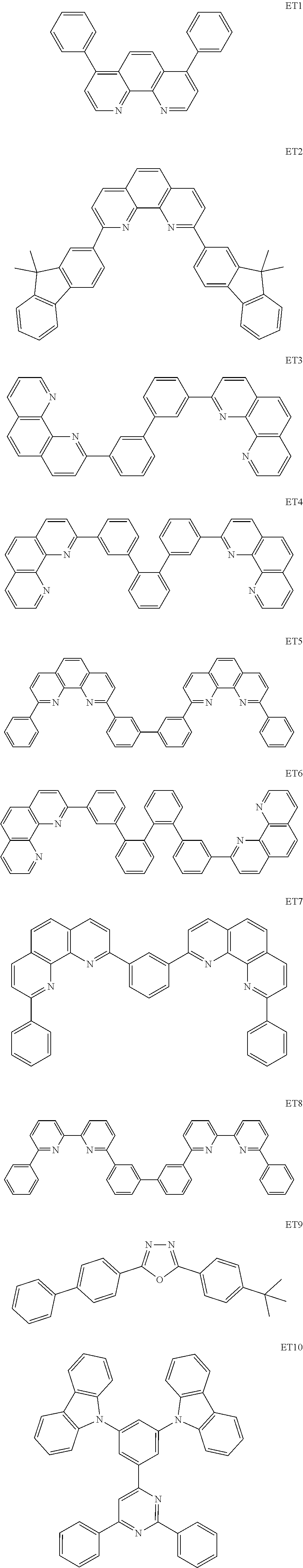

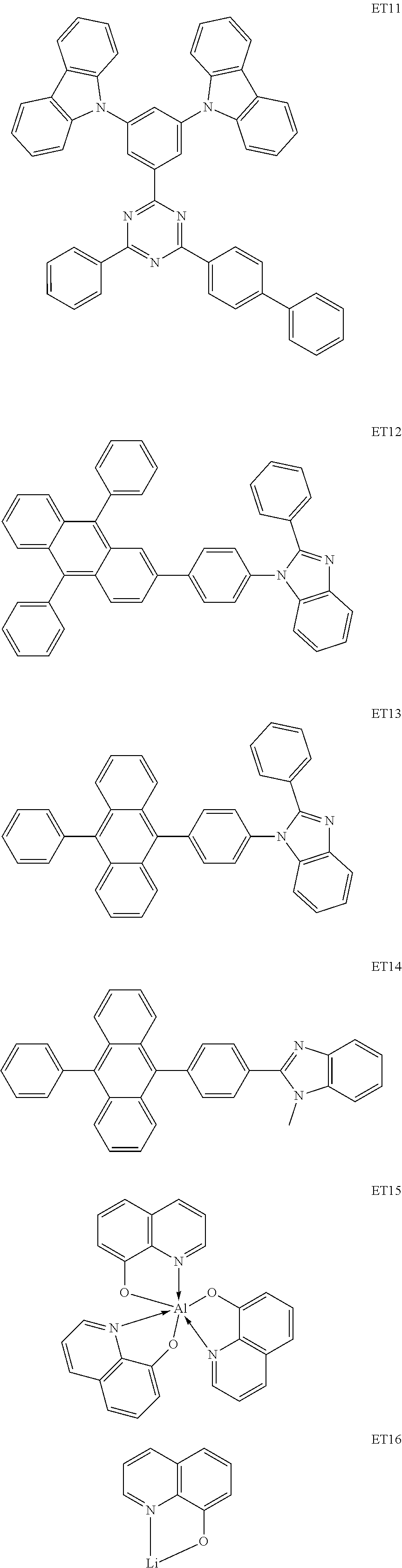

A material, such as ET1 to ET8, that has phenanthroline or pyridine in its molecular structure can be used in the electron transport layer 8. This is because such a material interacts with an electron injection material such as an alkali metal compound or an electrode material and thus has an effect of decreasing the electron injection barrier.

In the present disclosure, the electron injection layer 9 may be included. Any commonly known material can be used in the electron injection layer 9, and examples thereof include alkali metals, alkaline earth metals, rare earth metals, and compounds thereof. Specifically, metallic Ca, LiF, KF, Cs₂CO₃, or the like is used, and a mixture of any of these with the aforementioned electron transport materials may be used.

The organic compound layers constituting the organic light emitting element of the present disclosure can be formed by a dry process such as a vacuum deposition method, an ionized deposition method, sputtering, or plasma. Instead of the dry process, a wet process can be employed to form layers by a known coating method (for example, spin coating, dip coating, casting, a LB method, or an inkjet method) that involves dissolving the material in an appropriate solvent.

Here, when layers are formed by a vacuum deposition method or a solution coating method, for example, crystallization rarely occurs, and stability over time is improved. When films are formed by a coating method, an appropriate binder resin may be used in combination to form the films.

Examples of the binder resin include, but are not limited to, polyvinyl carbazole resin, polycarbonate resin, polyester resin, ABS resin, acrylic resin, polyimide resin, phenolic resin, epoxy resin, silicone resin, and urea resin.

These binder resins may be used alone as a homopolymer or in combination as a mixture of two or more to form a copolymer. If necessary, additives such as known plasticizers, oxidation inhibitors, and ultraviolet absorbents may be used in combination.

### Protection Layer

A protection layer may be disposed on the cathode 10. For example, by bonding a hygroscopic agent-laden glass onto the cathode 10, penetration of water and the like into organic compound layers can be reduced, and the incidence of display failures can be decreased. In another embodiment, a passivation film such as silicon nitride film may be disposed on the cathode 10 so as to reduce penetration of water and the like into the organic compound layers. For example, after the cathode 10 is formed, the cathode may be transported to another chamber without breaking the vacuum, and then a silicon nitride film having a thickness of 2 μm may be formed on the cathode by a CVD method to form a protection layer. Alternatively, after film deposition by the CVD method, a protection layer may be formed by an atomic layer deposition (ALD) method. The material for the film formed by the ALD method is not particularly limited and can be silicon nitride, silicon oxide, or aluminum oxide, for example. Silicon nitride may be further formed by a CVD method on the film formed by the ALD method. The film formed by the ALD method may be thinner than the film formed by the CVD method. Specifically, the thickness may be 50% or less or even 10% or less.

### Color Filter

A color filter may be formed on the protection layer. For example, a color filter that takes into account the size of the organic light emitting element may be disposed on a separate substrate, and this substrate may be bonded with the substrate on which the organic light emitting element has been formed, or a color filter may be formed by photolithographic patterning on the aforementioned protection layer. The color filter may be composed of a polymer.

### Planarization Layer

A planarization layer may be disposed between the color filter and the protection layer. The planarization layer is formed for the purpose of decreasing the irregularities of the underlying layer. Such a layer may also be referred to as a material resin layer without limiting the purpose. The planarization layer may be composed of an organic compound and may have a low molecular weight or a high molecular weight, preferably, a high molecular weight.

Planarization layers may be disposed above and under the color filter, and in such a case, the materials constituting the planarization layers may be the same or different. Specific examples thereof include polyvinyl carbazole resin, polycarbonate resin, polyester resin, ABS resin, acrylic resin, polyimide resin, phenolic resin, epoxy resin, silicone resin, and urea resin.

### Microlens

An organic light emitting element or an light emitting apparatus that includes the organic light emitting element may include an optical member, such as a microlens, on the light incident side thereof. The microlens can be composed of an acrylic resin, an epoxy resin, or the like. The microlens may be provided for the purposes of increasing the amount of light emerging from the organic light emitting element or the light emitting apparatus and controlling the direction in which the light emerges. The microlens may have a hemispherical shape. When the microlens has a hemispherical shape, there are tangent lines that contact the hemisphere, among which there is a tangent line parallel to the insulating layer, and the point of contact between that tangent line and the hemisphere is the apex of the microlens. The apex of the microlens can also be determined in the same manner from any cross-sectional view thereof. In other words, among the tangent lines that contact the semicircle of the microlens in a cross-sectional view, there is a tangent line parallel to the insulating layer, and the point of contact between that tangent line and the semicircle is the apex of the microlens.

Furthermore, the midpoint of the microlens can be defined. In a cross section of the microlens, a line segment extending from a point where the shape or an arc ends to another point where the shape of the arc ends is hypothetically drawn, and the midpoint of that line segment can be considered the midpoint of the microlens. The cross section used to determine the apex and the midpoint may be a cross section perpendicular to the insulating layer.

### Counter Substrate

A counter may be provided on the planarization layer. The counter substrate is called a counter substrate since the counter substrate is disposed at a position opposing the aforementioned substrate. The material constituting the counter substrate may be the same as the aforementioned substrate. The counter substrate may be a second substrate provided that the aforementioned substrate is a first substrate.

### Pixel Circuit

A light emitting apparatus that includes an organic light emitting element may include a pixel circuit connected to the organic light emitting element. The pixel circuit may be of an active matrix type that independently controls light emission of multiple organic light emitting elements. The active matrix circuit may be voltage-programmed or current-programmed. The drive circuit has a pixel circuit for each pixel.

The pixel circuit may include an organic light emitting element, a transistor that controls the emission luminance of the organic light emitting element, a transistor that controls the light emission timing, a capacitor that retains the gate voltage of the transistor that controls the emission luminance, and a transistor for establishing the connection to GND without a light emitting element.

The light emitting apparatus has a display region and a peripheral region around the display region. The display region includes pixel circuits, and the peripheral region includes display control circuits. The mobility of the transistor constituting the pixel circuit may be smaller than the mobility of the transistor constituting the display control circuit.

The gradient of the current-voltage characteristic of the transistor constituting the pixel circuit may be smaller than the gradient of the current-voltage characteristic of the transistor constituting the display control circuit. The gradient of the current-voltage characteristic can be measured by what is commonly known as Vg-Ig characteristics. The transistor constituting the pixel circuit is a transistor connected to a light emitting element, such as a first light emitting element.

### Pixels

The light emitting apparatus that includes the organic light emitting element may include multiple pixels. Each pixel has subpixels that emit light of colors different from one another. The subpixels may emit light of RGB colors, for example.

The pixel has a region also known as a pixel aperture that emits light. The pixel aperture may be 15 μm or less or 5 μm or more. More specifically, the pixel aperture may be, for example, 11 μm, 9.5 μm, 7.4 μm, or 6.4 μm. The distance between subpixels may be 10 μm or less, specifically, 8 μm, 7.4 μm, or 6.4 μm.

The pixels may be arranged into any known pixel matrix in a plan view. Examples thereof include a stripe matrix, a delta matrix, a pentile matrix, and a bayer matrix. The shape of the subpixels in a plan view may be any known shape. Examples thereof include rectangular shapes such as an oblong shape or a rhombus shape, and hexagonal shapes. Naturally, the shape does not have to be exact, and any shape close to an oblong shape is considered an oblong shape. The shape of the subpixels and the pixel arrangement may be used in combination.

### Usage of Organic Light Emitting Element

The organic light emitting element according to the present disclosure can be used as a member that constitutes a display apparatus or a lighting apparatus. Other examples of the usage include an exposure light source of an electrophotographic image forming apparatus, a backlight of a liquid crystal display apparatus, and a light emitting apparatus that has a color filter on a white light source.

The display apparatus may be an information processing apparatus that includes an image input unit through which image information is input from an area CCD, a linear CCD, a memory card, or the like, and an information processing unit that processes the input information, and that displays the input image on a display unit. The display apparatus may include multiple pixels, and at least one of the pixels may include the organic light emitting element of the present disclosure and a transistor connected to the organic light emitting element.

Furthermore, a display unit of an imaging apparatus or an ink jet printer may have a touch panel function. The driving system of the touch panel function may be infrared radiation, electrostatic capacitance, resistance film, electrostatic capacitance, or any other system. The display apparatus may be used in a display unit of a multifunctional printer.

Next, a display apparatus according to one embodiment is described with reference to the drawings.

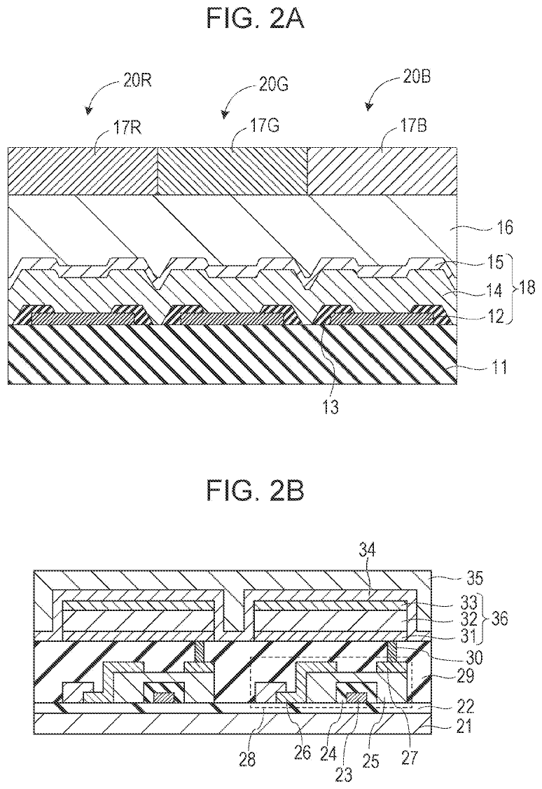

FIGS. 2A and 2B are schematic cross sectional views illustrating examples of a display apparatus that includes organic light emitting elements of the present disclosure and transistors connected to the organic light emitting elements.

FIG. 2A illustrates one example of a pixel which is a constitutional feature of the display apparatus of this embodiment. The pixel has subpixels 20. The subpixels are classified as 20R, 20G, and 20B according to their emission color. The emission color may be distinguished by the wavelength of the light emitted from the light emission layer, or a color filter or the like may be used to selectively transmit or change the color of the light emitted from the subpixels. Each of the subpixels has a first electrode 12 that serves as a reflection electrode disposed on an interlayer insulating layer 11, an insulating layer 13 that covers edges of the first electrode 12, an organic compound layer 14 that covers the first electrode 12 and the insulating layer 13, a second electrode 15, a protection layer 16, and a color filter 17. The first electrode 12, the organic compound layer 14, and the second electrode 15 constitute an organic light emitting element 18 of this embodiment.

The interlayer insulating layer 11 may have a transistor and a capacitor element below or inside thereof. The transistor and the first electrode 12 may be electrically connected to each other via a contact hole or the like not illustrated in the drawing.

The insulating layer 13 is also referred to as a bank or a pixel isolation film. The insulating layer 13 covers the edges of the first electrode 12 and surrounds the first electrode 12. The part where the insulating layer 13 is absent is in contact with the organic compound layer 14 and functions as a light-emitting region.

The second electrode 15 may be a transparent electrode, a reflection electrode, or a semi-transmissive electrode.

The protection layer 16 reduces penetration of moisture into the organic compound layer 14. Although the protection layer 16 is depicted as one layer in the drawing, the protection layer 16 may include multiple layers. An inorganic compound layer and an organic compound layer may be provided for each layer.

The color filters 17 are classified as 17R, 17G, and 17B according to their colors. The color filters may be formed on a planarizing film not illustrated in the drawing. A resin protection layer not illustrated in the drawing may be disposed on the color filters. The color filters 17 may be formed on the protection layer 16. Alternatively, the color filters 17 may be formed on a counter substrate such as a glass substrate and then bonded with the substrate.

A display apparatus illustrated in FIG. 2B includes an organic light emitting element 36 and a TFT 28 as one example of the transistor. Specifically, there are a substrate 21, such as glass or silicon, and an insulating layer 22 on top of the substrate 21, and a TFT 28 that includes a gate electrode 23, a gate insulating film 24, a semiconductor layer 25, a drain electrode 26, and a source electrode 27 is disposed on the insulating layer 22. An insulating film 29 is disposed on top of the TFT 28, and a contact hole 30 formed in the insulating film 29 connects an anode 31 of the organic light emitting element 36 to the source electrode 27.

Here, the type of electrical connection between the electrodes (anode 31 and cathode 33) included in the organic light emitting element 36 and the electrodes (source electrode 27 and drain electrode 26) included in the TFT 28 is not limited to the one illustrated in FIG. 2B. In other words, the type of electrical connection may be any as long as one of the anode 31 and the cathode 33 is electrically connected to one of the source electrode 27 and the drain electrode 26. The TFT 28 is a thin film transistor.

A first protection layer 34 and a second protection layer 35 are disposed on the cathode 33 to reduce deterioration of the organic light emitting element.

The emission luminance of the organic light emitting element 36 of the present embodiment is controlled by the TFT 28, and, by providing multiple organic light emitting elements 36 in-plane, an image can be displayed by using emission luminance.

The display apparatus illustrated in FIG. 2B uses a transistor as a switching element, but may use a different switching element instead.

The transistor used in the display apparatus illustrated in FIG. 2B is not limited to a TFT having an active layer on an insulating surface of a substrate and may be a transistor that uses a single-crystal silicon wafer. The active layer may be a non-single-crystal silicon such as amorphous silicon or microcrystalline silicon, or a non-single-crystal oxide semiconductor such as indium zinc oxide or indium gallium zinc oxide.

Alternatively, a transistor made of a low-temperature polysilicon or an active matrix driver formed on a substrate such as a Si substrate may be used. The phrase “on the substrate” can also mean “in the substrate”. Whether a transistor is formed in the substrate or a TFT is used is selected according to the size of the display unit; for example, when the size is about 0.5 inches, organic light emitting elements may be formed on a Si substrate. Here, the phrase “formed in the substrate” means that the transistor is produced by processing a substrate, such as a Si substrate, itself. In other words, “transistor in the substrate” can also be considered as that the substrate and the transistor are integrated.

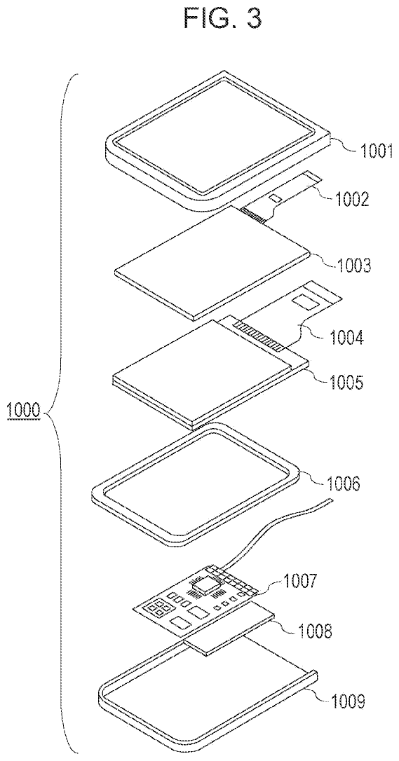

FIG. 3 is a schematic diagram illustrating one example of a display apparatus according to the present disclosure. A display apparatus 1000 includes an upper cover 1001 and a lower cover 1009, and a touch panel 1003, a display panel 1005, a frame 1006, a circuit substrate 1007, and a battery 1008 that are interposed between these covers.

The touch panel 1003 and the display panel 1005 are respectively connected to flexible print circuits FPC 1002 and 1004. Transistors are printed on the circuit substrate 1007. When the display apparatus is not a portable appliance, the battery 1008 may be omitted, and even when the display apparatus is a portable appliance, the battery 1008 may be provided at a different position.

The display apparatus of the present embodiment may include red, green and blue color filters. The color filters may be arranged so that red, green and blue are arranged in a delta matrix.

The display apparatus of the present embodiment may be used in a display unit of a portable terminal. Such a display apparatus may have both a display function and an operation function. Examples of the portable terminal include mobile phones such as smart phones, tablets, and head-mount displays.

The display apparatus of the present embodiment may be used in a display unit of an imaging apparatus that includes an optical unit having multiple lenses, and an imaging element that receives light that has passed through the optical unit. The imaging apparatus may include a display unit that displays the information acquired by the imaging element. The display unit may be exposed to the outside of the imaging apparatus or may be disposed in a finder. The imaging apparatus may be a digital camera or a digital camcorder.

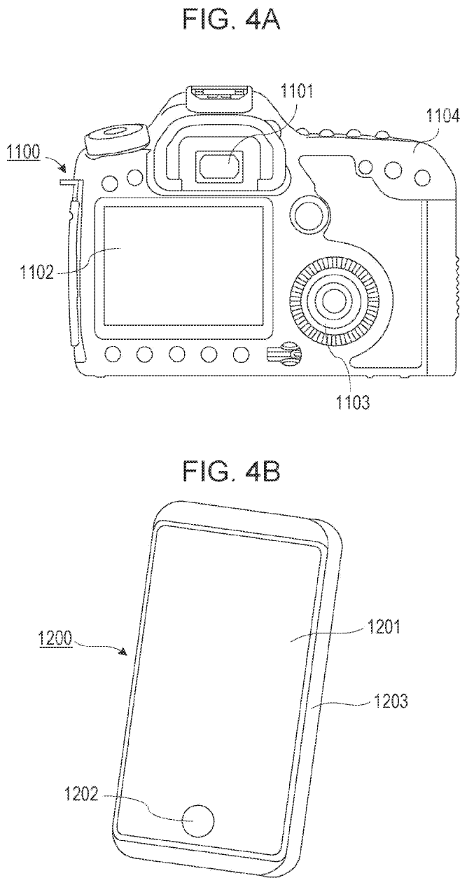

FIG. 4A is a schematic diagram illustrating one example of an imaging apparatus according to the present disclosure. An imaging apparatus 1100 includes a view finder 1101, a rear display 1102, an operation unit 1103, and a casing 1104. The view finder 1101 may include the display apparatus according to the present embodiment. In such a case, the display apparatus may display not only the image to be captured but also the environment information, imaging instructions, etc. The environment information may include the intensity of external light, the direction of the external light, the speed in which a photographic subject moves, and a possibility of the photographic subject becoming shielded by a shielding material.

Since the timing for imaging is very short, the information may be displayed as quickly as possible. Accordingly, a display apparatus that uses the organic light emitting element of the present disclosure can be used. This is because the organic light emitting element has a high response speed. In one embodiment, a display apparatus that uses an organic light emitting element is preferred over a liquid crystal display apparatus for the use in such devices required to achieve speedy display.

The imaging device 1100 includes an optical unit not illustrated in the drawing. The optical unit has multiple lenses, and an image is focused on the imaging element contained in the casing 1104. The multiple lenses can adjust the focal point by adjusting the relative positions thereof. This operation can be automated. The imaging apparatus may also be referred to as a photoelectric conversion apparatus. The photoelectric conversion apparatus can employ an imaging method that involves a method for detecting the difference from a previous image, a method for always cutting out an image from a recorded image, or the like instead of sequential imaging.

FIG. 4B is a schematic diagram illustrating one example of electronic equipment according to the present disclosure. Electronic equipment 1200 includes a display unit 1201, an operation unit 1202, and a casing 1203. The casing 1203 may include a circuit, a print substrate having the circuit, a battery, and a communication unit. The operation unit 1202 may be a button or a touch panel-system sensitive unit. The operation unit may be a biometric unit that performs, for example, unlocking through fingerprint recognition. The electronic equipment that includes the communication unit can also be called communication equipment. The electronic equipment may further have a camera function when equipped with a lens and an imaging element. The image captured through the camera function is displayed on the display unit. Examples of the electronic equipment include smart phones and laptop computers.

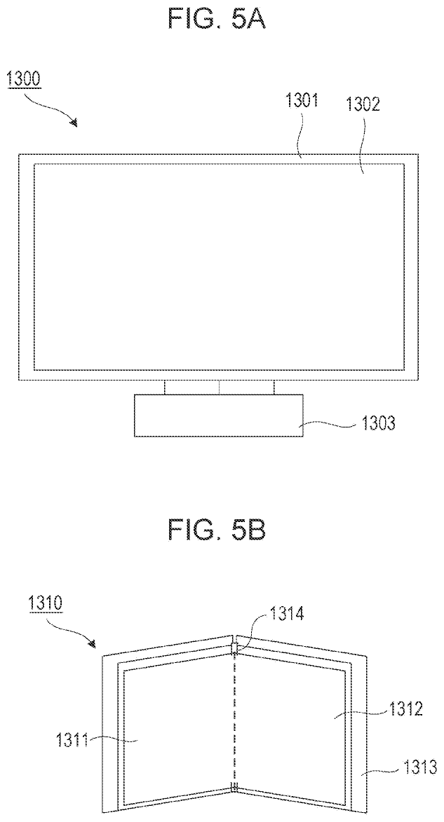

FIGS. 5A and 5B are schematic diagrams illustrating some examples of the display apparatus according to the present disclosure. FIG. 5A illustrates a display apparatus such as a television monitor or a PC monitor. A display apparatus 1300 includes a frame 1301 and a display unit 1302. The light emitting apparatus of the present disclosure may be used in the display unit 1302. The display apparatus 1300 further includes a base 1303 that supports the frame 1301 and the display unit 1302. The base 1303 is not limited to the type illustrated in FIG. 5A. The lower edge of the frame 1301 may also serve as the base. The frame 1301 and the display unit 1302 may be curved. The radius of curvature thereof may be 5000 mm or more and 6000 mm or less.

FIG. 5B is a schematic diagram illustrating another example of the display apparatus according to the present disclosure. A display apparatus 1310 illustrated in FIG. 5B is bendable, in other words, a foldable display apparatus. The display apparatus 1310 includes a first display unit 1311, a second display unit 1312, a casing 1313, and an inflection point 1314. The first display unit 1311 and the second display unit 1312 may each include a light emitting apparatus of the present disclosure. The first display unit 1311 and the second display unit 1312 may constitute one seamless display apparatus. The first display unit 1311 and the second display unit 1312 can be separated at the inflection point. The first display unit 1311 and the second display unit 1312 may display different images, or may together display one image.

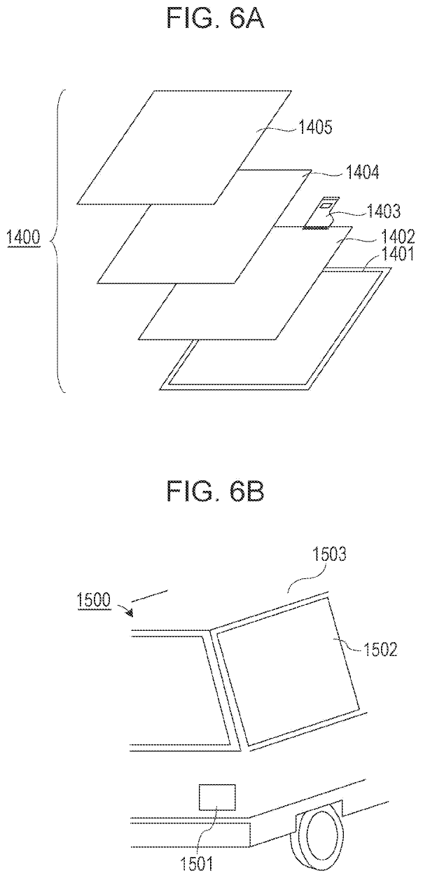

FIG. 6A is a schematic diagram illustrating one example of a lighting apparatus according to the present disclosure. A lighting apparatus 1400 includes a casing 1401, a light source 1402, a circuit substrate 1403, an optical filter 1404, and a light-diffusing unit 1405. The light source 1402 includes an organic light emitting element of the present disclosure. The optical filter 1404 may be a filter that improves the color rendering properties of the light source. The light-diffusing unit 1405 can effectively diffuse light from the light source 1402, such as for lighting up, and can deliver the light to a wide range. The optical filter 1404 and the light-diffusing unit 1405 may be disposed on the light emitting side of the lighting. If necessary, a cover may be provided on the outermost side.

The lighting apparatus is, for example, an apparatus that illuminates the room. The lighting apparatus may emit light that is white, neutral white, or any color from blue to red. The lighting apparatus may also include a light modulating circuit that modulates these types of light. The lighting apparatus includes an organic light emitting element of the present disclosure and a power supply circuit connected to the organic light emitting element. The power supply circuit is a circuit that converts AC voltage into DC voltage. White is a color that has a color temperature of 4200 K and the neutral white is a color that has a color temperature of 5000 K. The lighting apparatus may include a color filter.

The lighting apparatus of the present disclosure may include a heat releasing unit. The heat releasing unit is a unit that releases the heat inside the apparatus to the outside of the apparatus, and examples thereof include metals having a high specific heat, and liquid silicone.

FIG. 6B is a schematic diagram of an automobile which is one example of a moving body according to the present disclosure. The automobile includes a tail lamp, which is one example of a lighting unit. An automobile 1500 includes a tail lamp 1501 and may turn on the tail lamp upon braking operation or the like.

The tail lamp 1501 includes an organic light emitting element of the present disclosure. The tail lamp may also include a protection member that protects the organic light emitting element. The protection member may be composed of any material that has a sufficiently high strength and is transparent, and can be composed of polycarbonate or the like. The polycarbonate may be mixed with a furandicarboxylic acid derivative, an acrylonitrile derivative, or the like.

The automobile 1500 may include a car body 1503 and a window 1502 attached to the car body 1503. The window may be a transparent display if not a window for checking the front and rear sides of the automobile. This transparent display may include an organic light emitting element according to the present disclosure. In such a case, the materials constituting the electrodes, etc., of the organic light emitting element are transparent.

The moving body according to the present disclosure may be a ship, an airplane, a drone, or the like. The moving body includes a body and a lighting unit attached to the body. The lighting unit emits light to indicate the position of the body. The light unit includes an organic light emitting element of the present disclosure.

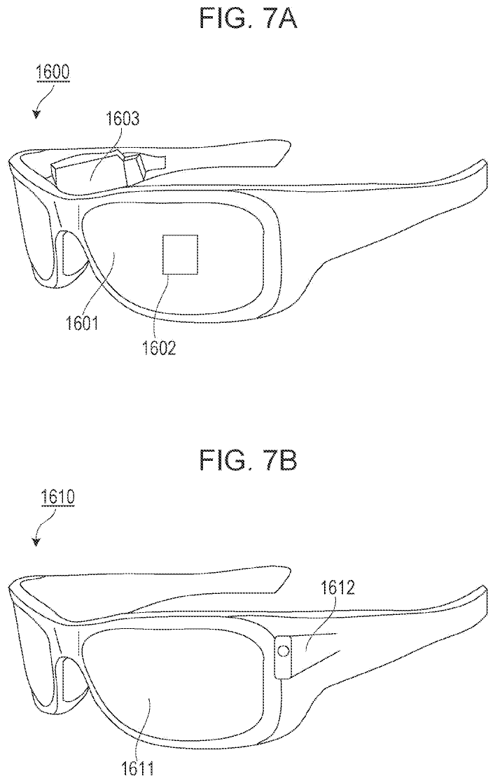

Referring now to FIGS. 7A and 7B, examples of applications of the display apparatuses of the aforementioned embodiments are described. The display apparatus can be applied to wearable device systems such as smart glasses, HMD, and smart contact lenses. An imaging display apparatus used in such application examples includes an imaging apparatus capable of converting visible light into electricity, and a display apparatus capable of emitting visible light.

FIG. 7A illustrates glasses 1600 (smart glasses) according to one application example. An imaging apparatus 1602 such as a CMOS sensor or SPAD is disposed on a front side of a lens 1601 of the glasses 1600. The display apparatus according to any of the embodiments described above is disposed on a rear side of the lens 1601.

The glasses 1600 further include a controller 1603. The controller 1603 functions as a power supply that supplies power to the imaging apparatus 1602 and the display apparatus of the embodiment. The controller 1603 also controls the operation of the imaging apparatus 1602 and the display apparatus. An optical system for focusing light onto the imaging apparatus 1602 is formed in the lens 1601.

FIG. 7B illustrates glasses 1610 (smart glasses) according to one application example. The glasses 1610 include a controller 1612, and the controller 1612 includes an imaging apparatus that corresponds to the imaging apparatus 1602 illustrated in FIG. 7A, and a display apparatus. In a lens 1611, an optical system for projecting light emitted from the display apparatus and the imaging apparatus in the controller 1612 is formed, and images are projected onto the lens 1611. The controller 1612 functions as a power supply that supplies power to the imaging apparatus and the display apparatus, and also controls the operation of the imaging apparatus and the display apparatus. The controller may include a line-of-sight detecting unit that detects the line of sight of a wearer. The line of sight may be detected by using infrared radiation. The infrared radiation emitting unit emits infrared radiation toward an eyeball of a user gazing the displayed image. A captured image of the eyeball is obtained when the imaging unit having a light receiving element detects reflection of the emitted infrared radiation from the eyeball. The degradation of the image quality is decreased by providing a unit for reducing light from the infrared radiation emitting unit to the display unit in a plan view.

The line of sight of the user with respect to the displayed image is detected from the captured image of the eyeball obtained by infrared imaging. Any known technique can be applied to the line-of-sight detection using the captured image of the eyeball. For example, a line-of-sight detection method based on a Purkinje image formed by reflection of the irradiated light at the cornea can be employed. More specifically, a line-of-sight detection process based on the pupil-corneal reflection method is performed. The line of sight of the user is detected by calculating the eye vector that indicates the direction (rotation angle) of the eyeball on the basis of the image of the pupil and the Purkinje image included in the captured image of the eyeball by using the pupil-corneal reflection method.

The display apparatus of the present disclosure may include an imaging apparatus that includes a light receiving element, and may control the image displayed on the display apparatus on the basis of the line-of-sight information of the user from the imaging apparatus. Specifically, in the display apparatus, a first view region that the user gazes and a second view region other than the first view region are determined on the basis of the line-of-sight information. The first view region and the second view region may be determined by the controller in the display apparatus, or may be determined by an external controller and received. In the display region of the display device, the display resolution of the first view region may be controlled to be higher than the display resolution of the second view region. In other words, the resolution of the second view region may be lower than that of the first view region.

The display region has a first display region and a second display region different from the first display region, and a region having a higher priority is determined from the first display region and the second display region on the basis of the line-of-sight information. The first display region and the second display region may be determined by the controller in the display apparatus, or may be determined by an external controller and received. The resolution of the region with higher priority may be controlled to be higher than the resolution of the region other than the region with higher priority. In other words, the resolution of a region having relatively low priority may be decreased.

An AI may be used to determine the first view region or the region with high priority. The AI may be a model configurated to estimate the angle of the line of sight and the distance to the object at the end of the line of sight from the image of the eyeball by using, as teaching data, the image of the eyeball and the direction in which the eyeball in the image was actually gazing. The AI program may be included in the display apparatus, the imaging apparatus, or an external apparatus. When an external apparatus includes the AI program, the data is transmitted to the display apparatus via communication.

When the display is controlled on the basis of the visual recognition, smart glasses that further include an imaging apparatus that captures the images of the outside can be implemented. The smart glasses can display the captured outside information in real time.

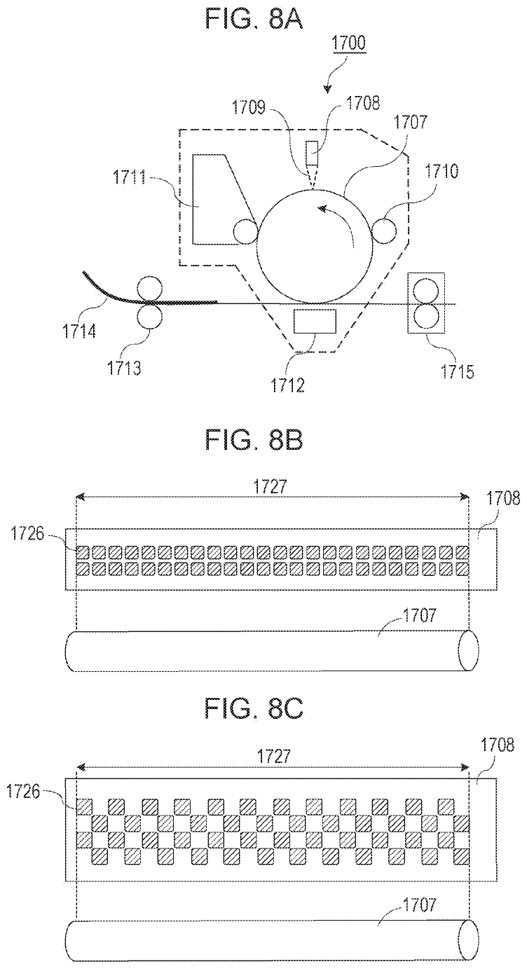

FIG. 8A is a schematic diagram illustrating one example of an image forming apparatus according to one embodiment of the present disclosure. An image forming apparatus 1700 is an electrophotographic image forming apparatus and includes a photosensitive body 1707, an exposure light source 1708, a charging unit 1710, a developing unit 1711, a transferring device 1712, a conveying roller 1713, and a fixing device 1715. Light 1709 is emitted from the exposure light source 1708, and an electrostatic latent image is formed on a surface of the photosensitive body 1707. The exposure light source 1708 includes the organic light emitting element of the present disclosure. The developing unit 1711 includes a toner etc. The charging unit 1710 charges the photosensitive body 1707. The transferring device 1712 transfers a developed image onto a recording medium 1714. The conveying roller 1713 conveys the recording medium 1714. The recording medium 1714 is, for example, a sheet of paper. The fixing device 1715 fixes the image formed on the recording medium 1714.

FIGS. 8B and 8C are schematic diagrams illustrating the exposure light source 1708 in which light emitting units 1726 are arranged on a long substrate. The arrow 1727 indicates the direction parallel to the axis of the photosensitive body as well as the direction in which rows of the organic light emitting elements are arranged. This row direction is coincident with the axis of rotation of the photosensitive body 1707. This direction can also be referred to as the longitudinal axis direction of the photosensitive body 1707. FIG. 8B is an arrangement in which the light emitting units 1726 are arranged along the longitudinal axis direction of the photosensitive body 1707. FIG. 8C illustrates an arrangement different from the one illustrated in FIG. 8B, in which the light emitting units 1726 in the first row and the second row are staggered. The first row and the second row are at different positions in the column direction. The first row includes multiple light emitting units 1726 with spaces therebetween. The second row includes light emitting units 1726 at positions corresponding to the spaces between the light emitting units 1726 in the first row. In other words, multiple light emitting units 1726 are arranged to be spaced from each other in the column direction also. The arrangement illustrated in FIG. 8C can also be referred to as a grid arrangement state, a houndstooth pattern, or a checkered pattern.

As described heretofore, by using apparatuses that use the organic light emitting element of the present disclosure, a display with excellent image quality and stable for a long period of time can be achieved.

### EXAMPLES

The present disclosure will now be described more specifically through Examples that do not limit the present disclosure.

### Measurement of Emission Spectrum and Absorption Spectrum

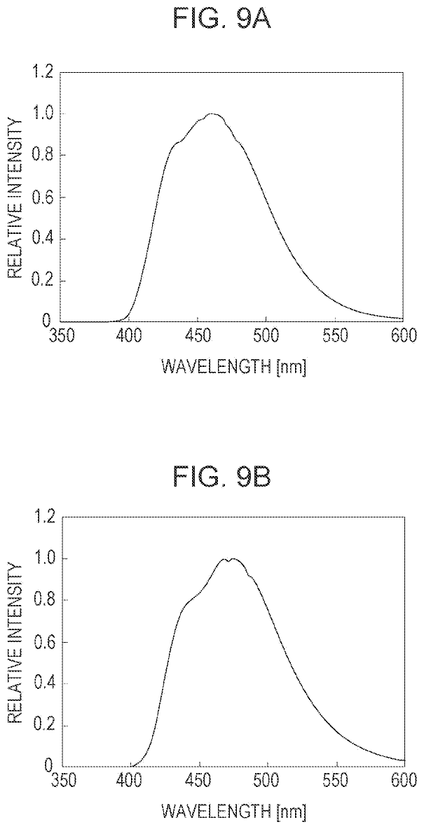

Each of the materials used in Examples and Comparative Examples described below was formed into a 30 nm-thick film on a quartz substrate. Then the photoluminescence at an excitation wavelength of 350 nm was measured with F-4500 produced by Hitachi Corporation at room temperature, and the absorption spectrum was measured with a UV/VIS spectrophotometer V-560 produced by JASCO International Co., Ltd. The obtained emission spectra and absorption spectra are indicated in FIGS. 9A to 14. The peak wavelength of the obtained emission spectrum and the longest wavelength-side peak wavelength in the absorption spectrum were determined, and the energy value (E) was calculated from formula (1) described above. The results are indicated in Table 1.

AD-17 and AD-18 in Table 1 are as follows. The materials other than AD-17 and AD-18 are the aforementioned specific examples of the host material and the light emitting dopant materials of the light emission layer.

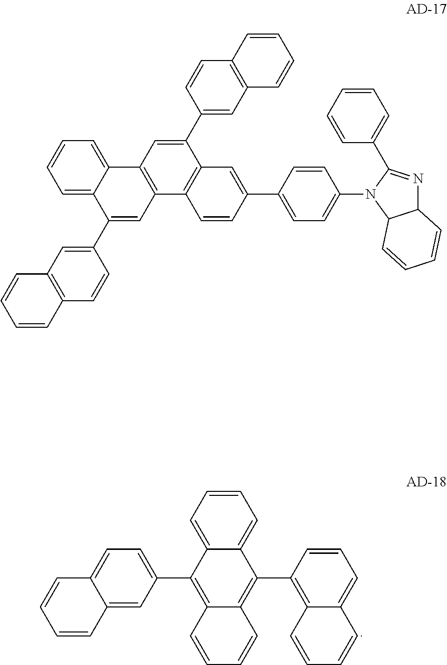

### Measurement of HOMO Level and LUMO Level

Each of the materials indicated in Table 1 was vapor-deposited on an aluminum substrate to a thickness of 30 nm, and the HOMO level was measured with AC-3 (produced by RIKEN KEIKI CO., LTD.). The value of the bandgap (B.G. in short) was obtained by converting the absorption edge in the aforementioned absorption spectrum measurement into the energy value (eV). Then the sum of the value of the HOMO level and the value of the bandgap was assumed to be the LUMO level. The results are indicated in Table 1.

It is possible that the hundredths places in the values of the HOMO level and the LUMO level indicated in Table 1 contain measurement errors. Thus, in the present disclosure, the hundredths places of the values of the energy levels were rounded and used as the reference for selecting the material in preparing the elements of Examples and Comparative Examples.

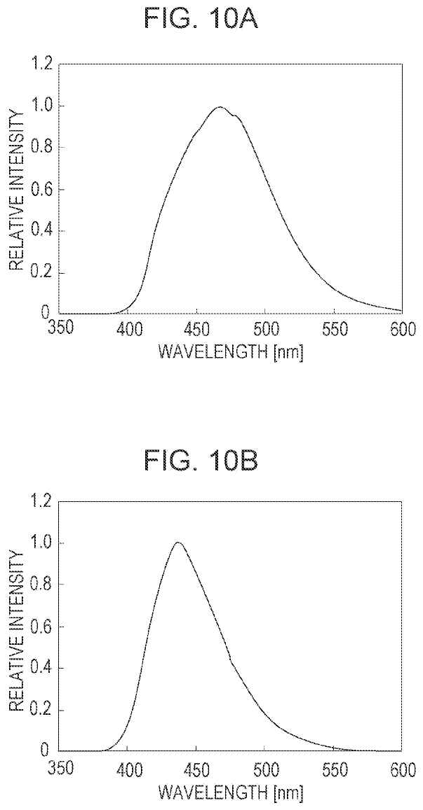

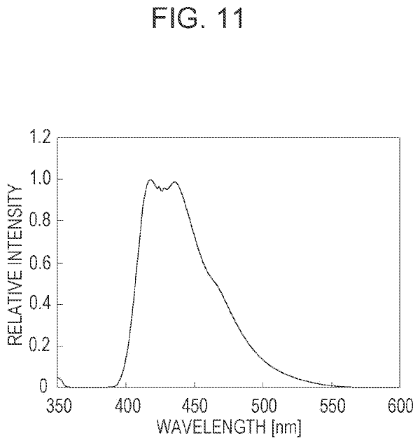

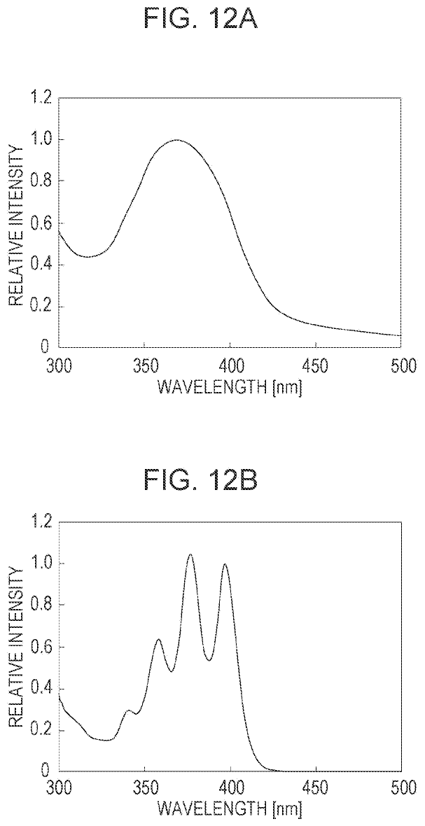

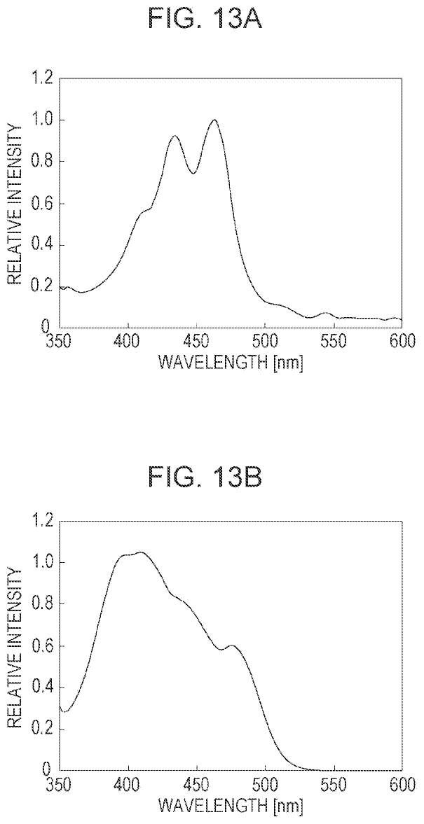

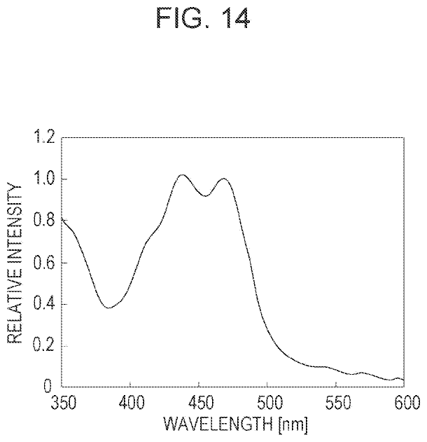

TABLE 1

| | Emission spectrum | | | Absorption spectrum | | | | | |
|---|---|---|---|---|---|---|---|---|---|
| | | Peak | | | Peak | | | | |
| | | Wavelength | E | | Wavelength | E | HOMO | LOMO | B.G. |
| | FIG. No. | (nm) | (eV) | FIG. No. | (nm) | (eV) | (eV) | (eV) | (eV) |
| AD-1 | FIG. 9A | 461 | 2.69 | — | — | — | −5.94 | −2.95 | 2.99 |
| AD-6 | FIG. 9B | 473 | 2.62 | FIG. 12A | 369 | 3.36 | −6.02 | −3.10 | 2.92 |
| AD-8 | FIG. 10A | 467 | 2.66 | — | — | — | −5.84 | −2.84 | 3.00 |
| AD-17 | FIG. 10B | 436 | 2.84 | — | — | — | −6.10 | −3.02 | 3.08 |
| AD-18 | FIG. 11 | 418 | 2.96 | FIG. 12B | 397 | 3.12 | −6.03 | −3.06 | 2.97 |
| H-1 | — | — | — | FIG. 13A | 463 | 2.68 | −5.77 | −3.23 | 2.54 |
| H-2 | — | — | — | FIG. 13B | 475 | 2.61 | −5.60 | −3.19 | 2.41 |
| H-3 | — | — | — | FIG. 14 | 467 | 2.66 | −5.76 | −3.30 | 2.46 |
| RD21 | — | — | — | — | | — | −6.03 | −3.06 | 2.97 |

### Example 1

A 40 nm-thick titanium (Ti) film was formed as an anode on a silicon substrate by a sputtering method and was photolithographically patterned so as to form regular hexagonal-Ti pixel array and wiring with a pixel pitch of 4.2 μm. A silicon nitride (SiN) insulating layer was formed on this Ti film and was photolithographically patterned so as to form a pixel array exposing Ti while the width of the SiN insulating layer that partitioned the pixels was 1 μm.

Subsequently, the water-washed substrate with the layers up to the insulating layer formed thereon, and the materials placed in a molybdenum or tungsten vapor deposition boat were installed in a vacuum vapor deposition apparatus, and UV/ozone washing was performed. After evacuating to 1.0×10⁻⁴ Pa (1×10⁻⁶ Torr), films were formed into a layer configuration indicated in Table 2 below, and the resulting substrate was transferred to a glove box and sealed with a desiccant-containing glass cap in a nitrogen atmosphere to obtain an organic light emitting element.

The obtained multilayer organic light emitting element satisfied the feature (1) of the present disclosure and the optional features (2) to (7) described above.

TABLE 2

| | | Film |
|---|---|---|
| | | thickness |
| | Material | (nm) |
| Cathode | Mg:Ag = 50:50 (volume ratio) | 15 |
| Electron injection layer | LiF | 1 |
| Electron transport layer | ET2 | 40 |
| Adjacent layer | AD-1 | 25 |
| Light emission layer | H-1:RD21 = 99.7:0.3 (volume | 20 |
| | ratio) | |
| Hole transport layer | HT2 | 40 |
| Hole injection layer | HT16 | 8 |

A voltage source was connected to the obtained organic light emitting element to evaluate the characteristics of the organic light emitting element. The voltage-current characteristic was measured with a pico ammeter 4140B produced by Hewlett-Packard Company, and the emission spectrum and the emission luminance were acquired by using SR-3 produced by TOPCON CORPORATION. The current efficiency determined from the emission luminance and the current value observed when light having a luminance of 30000 cd/m² was emitted was 10.3 cd/A, and the voltage was 4.6 V. The organic light emitting element had high current efficiency and low element voltage.

### Examples 2 to 4 and Comparative Examples 1 to 4

Organic light emitting elements were prepared as in Example 1 except that the adjacent layer material and the host material of the light emission layer were changed to the materials indicated in Table 3, and were evaluated in the same manner. The results are indicated in Table 3. In Table 3, “ΔE” represents the difference in energy value between the peak wavelength of the emission spectrum of the adjacent layer material and the longest wavelength-side peak wavelength in the absorption spectrum of the host material of the light emission layer.

TABLE 3

| | Adjacent | Light emission layer material | | | Current | Element |
|---|---|---|---|---|---|---|
| | layer | Host | Light emitting | ΔE | efficiency | voltage |
| | material | material | dopant material | (eV) | (cd/A) | (V) |
| Example 1 | AD-1 | H-1 | RD21 | 0.01 | 10.3 | 4.6 |
| Example 2 | AD-8 | H-1 | RD21 | 0.02 | 10.4 | 4.7 |
| Example 3 | AD-1 | H-2 | RD21 | 0.08 | 10.1 | 4.5 |
| Example 4 | AD-6 | H-3 | RD21 | 0.04 | 10.3 | 4.7 |
| Comparative | AD-17 | H-1 | RD21 | 0.16 | 8.8 | 4.8 |
| Example 1 | | | | | | |
| Comparative | AD-18 | H-1 | RD21 | 0.28 | 9.1 | 4.6 |
| Example 2 | | | | | | |
| Comparative | AD-1 | AD-18 | RD21 | 0.43 | 8.9 | 4.9 |
| Example 3 | | | | | | |
| Comparative | AD-18 | AD-6 | RD21 | 0.40 | 8.8 | 5.2 |
| Example 4 | | | | | | |

In Example 2, AD-8 had the HOMO level higher than AD-1 and was supposed to exhibit low hole blocking performance for preventing leakage of holes from the light emission layer; however, the current efficiency was not decreased. This shows that the current efficiency was high because of the effect of the disclosure, that is, because of the energy transfer to the host material in the light emission layer caused by recombination of holes, which had leaked from the light emission layer, in the adjacent layer. The organic light emitting elements of Examples 3 and 4 were also as excellent as Example 1.

In Comparative Example 1, the element voltage was high compared to Example 1, and, as indicated in Table 1, this is presumably due to AD-17 having a larger bandgap than AD-1. Furthermore, AD-17 has a lower HOMO level than AD-1 and is supposed to exhibit high hole blocking performance for preventing leakage of holes from the light emission layer; however, the current efficiency decreased. This shows that the effect of the present disclosure, that is, the energy transfer to the light emission layer host caused by recombination of holes, which had leaked from the light emission layer, in the adjacent layer, was weaker than in Example 1.

In Comparative Example 2, the HOMO level of AD-18 was lower than AD-1, and the holes leaking from the light emission layer do not easily enter the adjacent layer; however, the current efficiency was low compared to Example 1. This shows that the effect of the present disclosure, that is, the energy transfer to the light emission layer host material caused by recombination of holes, which had leaked from the light emission layer, in the adjacent layer, was weaker than in Example 1.

In Comparative Example 3, the current efficiency decreased, and this shows that the effect of the present disclosure, that is, the energy transfer to the light emission layer host caused by recombination of holes, which had leaked from the light emission layer, in the adjacent layer, was weaker than in Example 1.

In Comparative Example 4, the element voltage was high and the current efficiency decreased. This shows that the effect of the present disclosure, that is, the energy transfer to the host material in the light emission layer caused by recombination of holes, which had leaked from the light emission layer, in the adjacent layer, was weaker than in Example 1.

According to the present disclosure, an organic light emitting element that achieves both high light emission efficiency and low element voltage can be provided.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-012669 filed Jan. 31, 2023, which is hereby incorporated by reference herein in its entirety.

What is claimed is:

1. An organic light emitting element comprising:
an anode;
a cathode;
a light emission layer disposed between the anode and the cathode; and
an adjacent layer disposed in contact with a side of the light emission layer, the side facing the cathode,
wherein the light emission layer contains a host material and a light emitting dopant material,
the adjacent layer contains an adjacent layer material having a bandgap of 3.0 eV or less, and
a difference between an energy value at a peak wavelength of an emission spectrum of the adjacent layer material and an energy value at a peak wavelength of a longest-wavelength absorption band in an absorption spectrum of the host material is 0.15 eV or less.

2. The organic light emitting element according to claim 1, wherein the difference between the energy value at the peak wavelength of the emission spectrum of the adjacent layer material and the energy value at the peak wavelength of the longest-wavelength absorption band in the absorption spectrum of the host material is 0.10 eV or less.

3. The organic light emitting element according to claim 1, wherein HOMOh>HOMOa, where HOMOh represents an energy level of a HOMO of the host material and HOMOa represents an energy level of a HOMO of the adjacent layer material.

4. The organic light emitting element according to claim 1, wherein an emission color is red.

5. The organic light emitting element according to claim 1, wherein the host material includes a perylene moiety in a molecular structure thereof.

6. The organic light emitting element according to claim 1, wherein the light emitting dopant material includes a perylene moiety in a molecular structure thereof.

7. The organic light emitting element according to claim 1, wherein the adjacent layer material consists of a hydrocarbon.

8. The organic light emitting element according to claim 1, wherein the adjacent layer material includes a pyrene moiety in a molecular structure thereof.

9. A display apparatus comprising:
a plurality of pixels,
wherein at least one of the plurality of pixels includes the organic light emitting element according to claim 1 and a transistor connected to the organic light emitting element.

10. An imaging apparatus comprising:
an optical unit that includes a plurality of lenses;
an imaging element that receives light that has passed through the optical unit; and
a display unit that displays an image taken by the imaging element,
wherein the display unit includes the organic light emitting element according to claim 1.

11. Electronic equipment comprising:
a display unit that includes the organic light emitting element according to claim 1;
a casing in which the display unit is installed; and
a communication unit that communicates with outside and is installed in the casing.

12. A lighting apparatus comprising:
a light source that includes the organic light emitting element according to claim 1; and
a light-diffusing unit or an optical filter that transmits light emitted from the light source.

13. A moving body comprising:
a lighting unit that includes the organic light emitting element according to claim 1; and
a body in which the lighting unit is installed.

14. An exposure light source for an electrophotographic image forming apparatus, comprising the organic light emitting element according to claim 1.

15. The exposure light source according to claim 14, wherein the difference between the energy value at the peak wavelength of the emission spectrum of the adjacent layer material and the energy value at the peak wavelength of the longest-wavelength absorption band in the absorption spectrum of the host material is 0.10 eV or less.

16. The exposure light source according to claim 14, wherein HOMOh>HOMOa, where HOMOh represents an energy level of a HOMO of the host material and HOMOa represents an energy level of a HOMO of the adjacent layer material.

17. The exposure light source according to claim 14, wherein an emission color is red.

18. The exposure light source according to claim 14, wherein the host material includes a perylene moiety in a molecular structure thereof.

19. The exposure light source according to claim 14, wherein the light emitting dopant material includes a perylene moiety in a molecular structure thereof.

20. The exposure light source according to claim 14, wherein the adjacent layer material includes a pyrene moiety in a molecular structure thereof.
